(19) United States
(12) Patent Application Publication
(10) Pub. No.: US 2026/0026249 A1
(43) Pub. Date: Jan. 22, 2026

(54) DISPLAY DEVICE AND ELECTRONIC DEVICE INCLUDING THEREOF

(71) Applicant: Samsung Display Co., LTD., Yongin-si (KR)

(72) Inventors: Eon Joo LEE, Yongin-si (KR); Gee Bum KIM, Yongin-si (KR); Hyun Ho KIM, Yongin-si (KR); Bo Kwang SONG, Yongin-si (KR); Chaun Gi CHOI, Yongin-si (KR)

(21) Appl. No.: 19/083,241

(22) Filed: Mar. 18, 2025

(30) Foreign Application Priority Data
Jul. 22, 2024 (KR) 10-2024-0096172

(51) Int. Cl. H10K 59/80; H10K 59/122; H10K 59/40

(52) U.S. Cl. CPC H10K 59/8792; H10K 59/122; H10K 59/879; H10K 59/40

(57) ABSTRACT

A display device includes a substrate, a pixel electrode, a pixel defining film, a light emitting layer, a common electrode, an encapsulation layer, a first inorganic insulating film, a connection electrode, a second inorganic insulating film, a touch electrode connected to the connection electrode through a touch contact hole penetrating through the second inorganic insulating film, a third inorganic insulating film, a black matrix, a color filter covering a portion of the black matrix, and a first optical hole penetrating through the first to third inorganic insulating films.

### CROSS-REFERENCE TO RELATED APPLICATION

The present application claims priority to and the benefit of Korean Patent Application No. 10-2024-0096172, filed on Jul. 22, 2024, in the Korean Intellectual Property Office, the entire disclosure of which is incorporated herein by reference.

### BACKGROUND

### 1. Field

Aspects of some embodiments of the present disclosure relate to a display device and an electronic device including thereof.

### 2. Description of the Related Art

With the development of communication technology and media, display devices are being used to display images in various places and environments. For example, various types of display devices such as a liquid crystal display (LCD) and an organic light emitting display (OLED) are widely used.

The display device includes an anti-reflection member, such as a polarizing plate, attached on a display panel to reduce reflection of external light by metal lines of the display panel. Recently, in order to reduce the manufacturing cost of display devices, a color filter layer including color filters and a black matrix is used as the anti-reflection member instead of the polarizing plate.

The above information disclosed in this Background section is only for enhancement of understanding of the background and therefore the information discussed in this Background section does not necessarily constitute prior art.

### SUMMARY

Aspects of some embodiments the present disclosure include a display device that may be capable of increasing light emission efficiency when a color filter layer is used as an anti-reflection member instead of a polarizing plate.

According to some embodiments of the present disclosure, a display device includes a substrate, a pixel electrode on one surface of the substrate, a pixel defining film exposing a portion of the pixel electrode and defining a light emitting area, a light emitting layer on the pixel electrode in the light emitting area, a common electrode on the light emitting layer and the pixel defining film, an encapsulation layer on the common electrode, a first inorganic insulating film on the encapsulation layer, a connection electrode on the first inorganic insulating film, a second inorganic insulating film on the connection electrode and the first inorganic insulating film, a touch electrode on the second inorganic insulating film and connected to the connection electrode through a touch contact hole penetrating through the second inorganic insulating film, a third inorganic insulating film on the touch electrode, a black matrix on the third inorganic insulating film, a color filter on the third inorganic insulating film and covering a portion of the black matrix and a first optical hole penetrating through the first to third inorganic insulating films.

According to some embodiments, a refractive index of the color filter may be lower than a refractive index of the first inorganic insulating film, a refractive index of the second inorganic insulating film, and a refractive index of the third inorganic insulating film.

According to some embodiments, in a plan view, a minimum distance from the pixel defining film to the first optical hole adjacent to the pixel defining film in one direction may be shorter than a width of the first optical hole in the one direction.

According to some embodiments, in plan view, the minimum distance from the pixel defining film to the first optical hole adjacent to the pixel defining film in the one direction may be 0.3 μm to 4 μm.

According to some embodiments, in plan view, a minimum distance from the pixel defining film to the black matrix adjacent to the pixel defining film in one direction may be greater than a width of the first optical hole.

According to some embodiments, the color filter may fill an entirety of the first optical hole.

According to some embodiments, the black matrix may be spaced apart from the first optical hole.

According to some embodiments, the color filter may fill a portion of the first optical hole.

According to some embodiments, the black matrix may fill a remaining portion of the first optical hole.

According to some embodiments, a portion of the third inorganic insulating film may be on the first optical hole.

According to some embodiments, a refractive index of the third inorganic insulating film may be lower than a refractive index of the first inorganic insulating film and a refractive index of the second inorganic insulating film.

According to some embodiments, an angle formed between a lower surface of the first inorganic insulating film and a side surface of the optical hole may be 50° to 70°

According to some embodiments, the display device may further include an organic film between the encapsulation layer and the color filter and a second optical hole defined between the organic film and the first inorganic insulating film, between the organic film and the second inorganic insulating film, and between the organic film and the third inorganic insulating film.

According to some embodiments, in plan view, the first optical hole may surround the second optical hole.

According to some embodiments, a refractive index of the organic film may be lower than a refractive index of the color filter.

According to some embodiments, the refractive index of the organic film may be lower than a refractive index of the first inorganic insulating film, a refractive index of the second inorganic insulating film, and a refractive index of the third inorganic insulating film.

According to some embodiments, the organic film may overlap the light emitting layer.

According to some embodiments, a lower surface of the organic film may be longer than an upper surface of the organic film, and a side surface of the organic film may be formed to flatly connect the upper and lower surfaces of the organic film.

According to some embodiments, an angle formed by the side surface of the organic film and the lower surface of the organic film may be 50° to 70°.

According to some embodiments of the present disclosure, a display device includes a substrate, a pixel electrode on one surface of the substrate, a pixel defining film exposing a portion of the pixel electrode and defining a light emitting area, a light emitting layer on the pixel electrode in the light emitting area, a common electrode on the light emitting layer and the pixel defining film, an encapsulation layer on the common electrode, a plurality of inorganic insulating films on the encapsulation layer and a touch electrode between the plurality of inorganic insulating films, a black matrix on the plurality of inorganic insulating films, color filters on the plurality of inorganic insulating films and covering portions of the black matrix and an optical hole penetrating through the plurality of inorganic insulating films. The color filters include a first color filter configured to transmit light of a first color, a second color filter configured to transmit light of a second color different from the first color, and a third color filter configured to transmit light of a third color different from the first and second colors.

According to some embodiments, in a plan view, a minimum length from the pixel defining film to an optical hole of the first color filter adjacent to the pixel defining film in one direction may be defined as a first length, in a plan view, a minimum length from the pixel defining film to an optical hole of the second color filter adjacent to the pixel defining film in one direction may be defined as a second length, and the second length may be longer than the first length.

According to some embodiments, in a plan view, a minimum length from the pixel defining film to an optical hole of the third color filter adjacent to the pixel defining film in one direction may be defined as a third length, and the third length may longer than the second length.

According to some embodiments of the present disclosure, an electronic device includes a display device, the display device including a substrate, a pixel electrode on one surface of the substrate, a pixel defining film exposing a portion of the pixel electrode and defining a light emitting area, a light emitting layer on the pixel electrode in the light emitting area, a common electrode on the light emitting layer and the pixel defining film, an encapsulation layer on the common electrode, a first inorganic insulating film on the encapsulation layer, a connection electrode on the first inorganic insulating film, a second inorganic insulating film on the connection electrode and the first inorganic insulating film, a touch electrode on the second inorganic insulating film and connected to the connection electrode through a touch contact hole penetrating through the second inorganic insulating film, a third inorganic insulating film on the touch electrode, a black matrix on the third inorganic insulating film, a color filter on the third inorganic insulating film and covering a portion of the black matrix and a first optical hole penetrating through the first to third inorganic insulating films.

However, aspects of embodiments according to the present disclosure are not restricted to those set forth herein. The above and other aspects of some embodiments of the present disclosure will become more apparent to one of ordinary skill in the art to which the present disclosure pertains by referencing the detailed description of the present disclosure given below.

In a display device according to some embodiments, light traveling toward the black matrix may be refracted toward the front of the display device by arranging or forming the inorganic insulating film with a higher refractive index than the color filters below the color filters and forming the optical hole including the color filters between the inorganic insulating film and the black matrix. Accordingly, luminance in the front direction of the display device may be relatively improved.

In a display device according to some embodiments, the first to third inorganic insulating film having a higher refractive index than the color filters may be below the color filters, and the optical hole defined by the first and second inorganic insulating films may be formed. In this case, the refractive index of the third inorganic insulating film at the top may be lower than the refractive indexes of the first and second inorganic insulating films, and the optical hole may include the third inorganic insulating film. Accordingly, the light traveling toward the black matrix may be refracted once between the second and third inorganic insulating films, and once more between the third inorganic insulating film and the color filters. Through this, as the light that was traveling closer to the black matrix is also emitted in the front direction of the display device, the luminance in the front direction of the display device may be relatively improved.

In addition, an organic film with a lower refractive index than the color filters may be in the area overlapping the light emitting portion, and the optical hole including the color filters may be formed between the organic film and the inorganic insulating film. Light passing through the organic film and through the side surface of the optical hole to the color filters may be refracted in the side direction of the display device. Through this, the luminance of the display device may relatively increase when the display device is observed from the side.

However, the characteristics of embodiments are not restricted to the one set forth herein. The above and other effects of the embodiments will become more apparent to one of ordinary skilled in the art to which the embodiments pertain by referencing the appended claims, and their equivalents.

### BRIEF DESCRIPTION OF THE DRAWINGS

The above and other characteristics and features of embodiments according to the present disclosure will become more apparent by describing further details of some embodiments thereof with reference to the attached drawings, in which:

FIG. 1 is a perspective view of a display device according to some embodiments of the present disclosure;

FIG. 2 is a plan view of the display device of FIG. 1;

FIG. 3 is a side view of the display device of FIG. 1;

FIG. 4 is a layout view illustrating the touch sensing layer of FIG. 3;

FIG. 5 is an enlarged view of the area A of FIG. 4;

FIG. 6 is an enlarged view of a PX area of FIG. 5;

FIG. 7 is a cross-sectional view of the display panel taken along the line P-P′ of FIG. 6;

FIG. 8 is a cross-sectional view of the display panel taken along the line Q-Q′ of FIG. 6;

FIG. 9 is a cross-sectional view of the display panel taken along the line R-R′ of FIG. 6;

FIG. 10 is an enlarged view of the area B of FIG. 7;

FIG. 11 is an enlarged view of the area B-1 of FIG. 10;

FIG. 12 is a cross-sectional view of the display panel taken along the line P-P′ of FIG. 6;

FIG. 13 is an enlarged view of the area C of FIG. 12;

FIG. 14 is a cross-sectional view of the display panel taken along the line P-P′ of FIG. 6;

FIG. 15 is an enlarged view of the area D of FIG. 14;

FIG. 16 is an enlarged view of D-1 area of FIG. 15;

FIG. 17 is a layout view illustrating another example of the light emitting area of FIG. 5;

FIG. 18 is a cross-sectional view of the display panel taken along the line P-P′ of FIG. 6;

FIG. 19 is an enlarged view of the area E of FIG. 18;

FIG. 20 is an enlarged view of the area E-1 of FIG. 19.

### DETAILED DESCRIPTION

Aspects and features of embodiments of the present disclosure and methods of accomplishing the same may be understood more readily by reference to the detailed description of embodiments and the accompanying drawings. Hereinafter, embodiments will be described in more detail with reference to the accompanying drawings. The described embodiments, however, may be embodied in various different forms, and should not be construed as being limited to only the illustrated embodiments herein. Rather, these embodiments are provided as examples so that the present disclosure will be thorough and complete, and will fully convey the aspects and features of the present disclosure to those skilled in the art. Accordingly, processes, elements, and techniques that are not necessary to those having ordinary skill in the art for a complete understanding of the aspects and features of the present disclosure might not be described.

Unless otherwise noted, like reference numerals, characters, or combinations thereof denote like elements throughout the attached drawings and the written description, and thus, descriptions thereof will not be repeated. Further, parts not related to the description of one or more embodiments might not be shown to make the description clear.

In the drawings, the relative sizes of elements, layers, and regions may be exaggerated for clarity. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result, for example, of manufacturing techniques and/or tolerances, are to be expected. Further, specific structural or functional descriptions disclosed herein are merely illustrative for the purpose of describing embodiments according to the present disclosure. Thus, embodiments disclosed herein should not be construed as limited to the particular illustrated shapes of regions, but are to include deviations in shapes that result from, for instance, manufacturing.

For example, an implanted region illustrated as a rectangle may have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the drawings are schematic in nature and their shapes are not intended to illustrate the actual shape of a region of a device and are not intended to be limiting. Additionally, as those skilled in the art would realize, the described embodiments may be modified in various different ways, all without departing from the spirit or scope of the present disclosure.

In the detailed description, for the purposes of explanation, numerous specific details are set forth to provide a thorough understanding of various embodiments. It is apparent, however, that various embodiments may be practiced without these specific details or with one or more equivalent arrangements. In other instances, well-known structures and devices are shown in block diagram form to avoid unnecessarily obscuring various embodiments.

Spatially relative terms, such as “beneath,” “below,” “lower,” “under,” “above,” “upper,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below” or “beneath” or “under” other elements or features would then be oriented “above” the other elements or features. Thus, the example terms “below” and “under” can encompass both an orientation of above and below.

The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, in this specification, the phrase “on a plane,” or “in a plan view,” means viewing a target portion from the top, and the phrase “on a cross-section” means viewing a cross-section formed by vertically cutting a target portion from the side.

It will be understood that when an element, layer, region, or component is referred to as being “formed on,” “on,” “connected to,” or “coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. For example, when a layer, region, or component is referred to as being “electrically connected” or “electrically coupled” to another layer, region, or component, it can be directly electrically connected or coupled to the other layer, region, and/or component or intervening layers, regions, or components may be present. However, “directly connected/directly coupled” refers to one component directly connecting or coupling another component without an intermediate component. Meanwhile, other expressions describing relationships between components such as “between,” “immediately between” or “adjacent to” and “directly adjacent to” may be construed similarly. In addition, it will also be understood that when an element or layer is referred to as being “between” two elements or layers, it can be the only element or layer between the two elements or layers, or one or more intervening elements or layers may also be present.

For the purposes of the present disclosure, expressions such as “at least one of,” “one of,” and “selected from,” when preceding a list of elements, modify the entire list of elements and do not modify the individual elements of the list. For example, “at least one of X, Y, and Z,” “at least one of X, Y, or Z,” and “at least one selected from the group consisting of X, Y, and Z” may be construed as X only, Y only, Z only, any combination of two or more of X, Y, and Z, such as, for instance, XYZ, XYY, XZ, YZ, and ZZ, or any variation thereof. Similarly, the expression such as “at least one of A and/or B” may include A, B, or A and B. As used herein, the term “and/or” includes any and all combinations of one or more of the associated listed items. For example, the expression such as “A and/or B” may include A, B, or A and B. Further, the use of “may” when describing embodiments of the present disclosure refers to “one or more embodiments of the present disclosure”.

It will be understood that, although the terms “first,” “second,” “third,” etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing particular embodiments only and is not intended to be limiting of the present disclosure. As used herein, the singular forms “a” and “an” are intended to include the plural forms as well, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

As used herein, the term “substantially,” “about,” “approximately,” and similar terms are used as terms of approximation and not as terms of degree, and are intended to account for the inherent deviations in measured or calculated values that would be recognized by those of ordinary skill in the art. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value. Further, the use of “may” when describing embodiments of the present disclosure refers to “one or more embodiments of the present disclosure.”

When one or more embodiments may be implemented differently, a specific process order may be performed differently from the described order. For example, two consecutively described processes may be performed substantially at the same time or performed in an order opposite to the described order.

Also, any numerical range disclosed and/or recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, for example, having a minimum value equal to or greater than 1.0 and a maximum value equal to or less than 10.0, such as, for example, 2.4 to 7.6. Any maximum numerical limitation recited herein is intended to include all lower numerical limitations subsumed therein, and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein. All such ranges are intended to be inherently described in this specification such that amending to expressly recite any such subranges would comply with the requirements of 35 U.S.C. § 112(a) and 35 U.S.C. § 132(a).

The electronic or electric devices and/or any other relevant devices or components according to one or more embodiments of the present disclosure described herein may be implemented utilizing any suitable hardware, firmware (e.g., an application-specific integrated circuit), software, or a combination of software, firmware, and hardware. For example, the various components of these devices may be formed on one integrated circuit (IC) chip or on separate IC chips. Further, the various components of these devices may be implemented on a flexible printed circuit film, a tape carrier package (TCP), a printed circuit board (PCB), or formed on one substrate.

Further, the various components of these devices may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the spirit and scope of the present disclosure.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning for example consistent with their meaning in the context of the relevant art and/or the present specification, and should not be interpreted in an idealized or overly formal sense, unless expressly so defined herein.

Specific embodiments are described below with reference to the attached drawings.

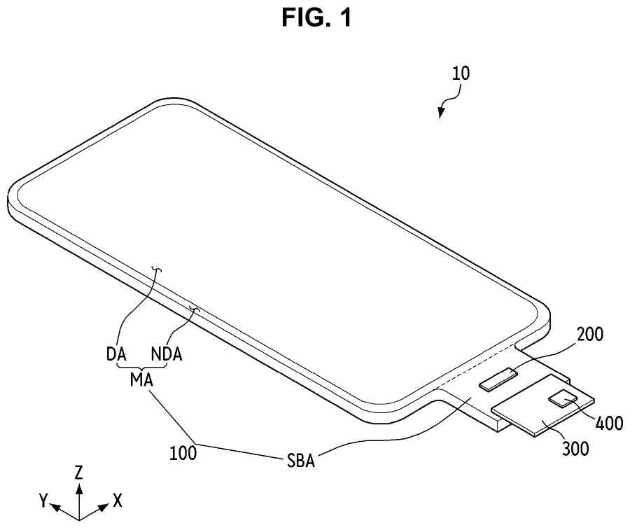

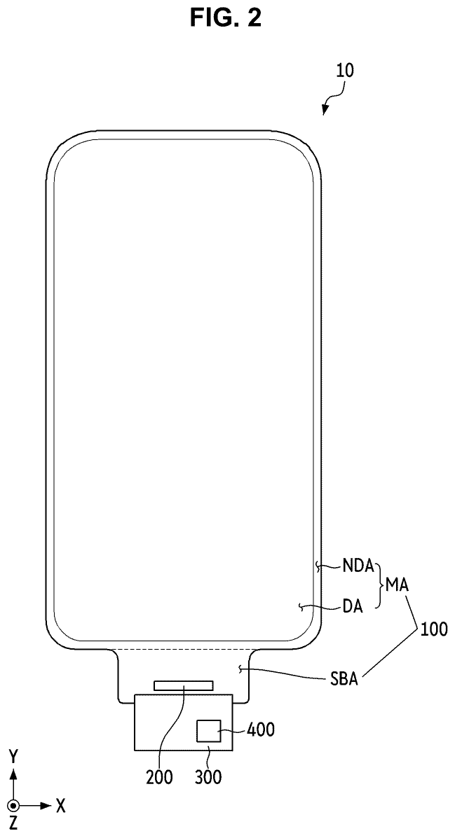

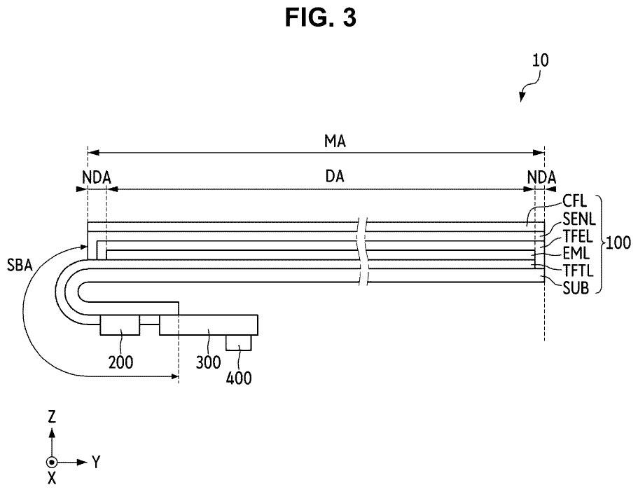

FIG. 1 is a perspective view of a display device according to some embodiments of the present disclosure and FIG. 2 is a plan view of the display device of FIG. 1. FIG. 3 is a side view of the display device of FIG. 1.

Referring to FIGS. 1 to 3, a display device 10 according to some embodiments may be applied to portable electronic devices such as mobile phones, smartphones, tablet personal computers (PCs), mobile communication terminals, electronic notebooks, electronic books, portable multimedia players (PMPs), navigation devices, and ultra mobile PCs (UMPCs). Alternatively, the display device 10 according to some embodiments may be applied as a display unit of a television, a laptop 1 computer, a monitor, a billboard, or the Internet of Things (IoT). Alternatively, the display device 10 according to some embodiments may be applied to wearable devices such as a smart watch, a watch phone, a glasses-type display, and a head mounted display (HMD). Alternatively, the display device 10 according to some embodiments may be applied to an instrument panel of a vehicle, a center fascia of a vehicle, a center information display (CID) located on a dashboard of a vehicle, a room mirror display substituting for a side mirror of a vehicle, or a display located on a rear surface of a front seat as entertainment for a rear seat of a vehicle.

The display device 10 may be a light emitting display device such as an organic light emitting display device using an organic light emitting diode, a quantum dot light emitting display device including a quantum dot light emitting layer, an inorganic light emitting display device including an inorganic semiconductor, and a micro light emitting display device using a micro or nano light emitting diode (micro or nano LED). Hereinafter, it is mainly described that the display device 10 is the organic light emitting display device, but embodiments according to the present disclosure are not limited thereto.

The display device 10 includes a display panel 100, a display driving circuit 200, a display circuit board 300, and a touch driving circuit 400.

The display panel 100 may be formed in a rectangular plane having short

sides in a first direction (X-axis direction) and long sides in a second direction (Y-axis direction) intersecting the first direction (X-axis direction). A corner where the short side in the first direction (X-axis direction) and the long side in the second direction (Y-axis direction) meet may be rounded to have a curvature (e.g., a set or predetermined curvature) or may be formed at a right angle. The planar shape of the display panel 100 is not limited to the quadrangular shape, and may be formed in other polygonal shapes, a circular shape, or an elliptical shape. The display panel 100 may be formed to be flat, but is not limited thereto. For example, the display panel 100 includes curved portions that are formed at left and right distal ends and have a constant curvature or a varying curvature. In addition, the display panel 100 may be flexibly formed to be curved, bent, folded, or rolled.

The display panel 100 includes a main area MA and a sub-area SBA.

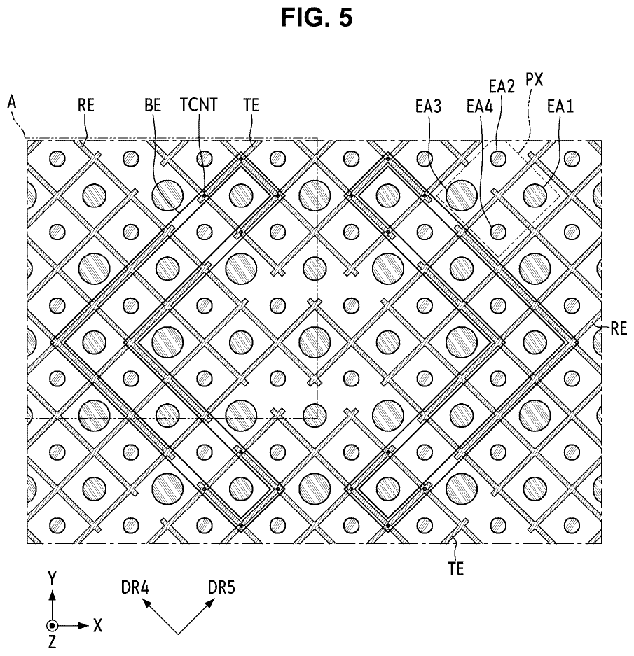

The main area MA includes a display area DA displaying images and a non- display area NDA which is a peripheral area (e.g., surrounding or outside a footprint) of the display area DA. The display area DA includes pixels (PX in FIG. 5) that display an image. The sub-area SBA may protrude in an opposite direction of the second direction (Y-axis direction) from one side of the main area MA.

It is illustrated in FIGS. 1 and 2 that the sub-area SBA is unfolded, but the sub-area SBA may be bent as illustrated in FIG. 3, and in this case, the sub-area SBA may be located on a lower surface of the display panel 100. When the sub-area SBA is bent, the sub-area SBA may overlap the main area MA in a thickness direction (Z-axis direction) of a substrate SUB. The display driving circuit 200 may be located in the sub-area SBA.

In addition, the display panel 100 may include a substrate SUB, a thin film transistor layer TFTL, a light emitting element layer EML, an encapsulation layer TFEL, a touch sensing layer SENL, and a color filter layer CFL, as illustrated in FIG. 3.

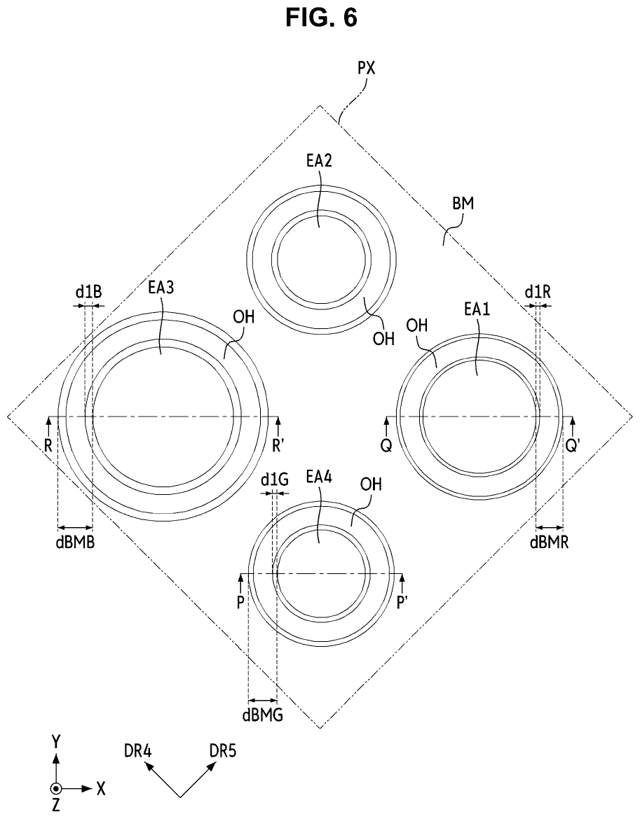

The thin film transistor layer TFTL may be located on the substrate SUB. The thin film transistor layer TFTL may be located in the main area MA and the sub-area SBA. The thin film transistor layer TFTL includes transistors (TR in FIG. 6).

The light emitting element layer EML may be located on the thin film transistor layer TFTL. The light emitting element layer EML may be located in the display area DA of the main area MA. The light emitting element layer EML includes light emitting elements located in light emitting portions.

The encapsulation layer TFEL may be located on the light emitting element layer EML. The encapsulation layer TFEL may be located in the display area DA and the non-display area NDA of the main area MA. The encapsulation layer TFEL includes at least one inorganic film and at least one organic film for encapsulating the light emitting element layer.

The touch sensing layer SENL may be located on the encapsulation layer TFEL. The touch sensing layer SENL may be located in the display area DA and the non-display area NDA of the main area MA. The touch sensing layer SENL may sense a touch of a person or an object using sensor electrodes.

The color filter layer CFL may be located on the touch sensing layer SENL. The color filter layer CFL may be located in the display area DA and the non-display area NDA of the main area MA. The color filter layer CFL may be an anti-reflection member for relatively reducing external light from being reflected from metal lines and metal electrodes of the display panel 100. The color filter layer CFL includes a plurality of color filters. For example, the color filter layer CFL includes a first color filter transmitting light of a first wavelength range, a second color filter transmitting light of a second wavelength range, and a third color filter transmitting light of a third wavelength range.

A cover window for protecting an upper portion of the display panel 100 may be located on the color filter layer CFL. The cover window may be attached onto the color filter layer CFL by a transparent adhesive member such as an optically clear adhesive (OCA) film or an optically clear resin (OCR). The cover window may also be made of an inorganic material such as glass or also be made of an organic material such as plastic or a polymer material.

The display driving circuit 200 may generate signals and voltages for driving the display panel 100. The display driving circuit 200 may be formed as an integrated circuit (IC) and may be attached onto the display panel 100 in a chip on glass (COG) manner, a chip on plastic (COP) manner, or an ultrasonic bonding manner, but is not limited thereto. For example, the display driving circuit 200 may be attached onto the display circuit board 300 in a chip on film (COF) method.

The display circuit board 300 may be attached to one end of the sub-area SBA of the display panel 100. Therefore, the display circuit board 300 may be electrically connected to the display panel 100 and the display driving circuit 200. The display panel 100 and the display driving circuit 200 may receive digital video data, timing signals, and driving voltages through the display circuit board 300. The display circuit board 300 may be a flexible film such as a flexible printed circuit board, a printed circuit board, or a chip on film.

The touch driving circuit 400 may be located on the display circuit board 300. The touch driving circuit 400 may be formed as an integrated circuit (IC) and attached onto the display circuit board 300.

The touch driving circuit 400 may be connected to sensor electrodes of the touch sensing layer SENL of the display panel 100. The touch driving circuit 400 applies driving signals to the sensor electrodes of the touch sensing layer SENL and measures mutual capacitance values of the sensor electrodes. The driving signal may be a signal having a plurality of driving pulses. The touch driving circuit 400 may determine whether the user has touched or is in proximity based on the mutual capacitance values. The touch of the user indicates that an object such as a user's finger or a pen comes into direct contact with one surface of the display device 10 located on the touch sensing layer SENL. The user's proximity indicates that the object such as the user's finger or the pen is hovering over one surface of the display device 10.

As illustrated in FIGS. 1 to 3, in order to relatively reduce reflection of external light by the metal lines and the metal electrodes of the display panel 100, the display panel 100 includes the color filter layer CFL including the color filters. Accordingly, there is no need to attach a separate anti-reflection member such as a polarizing plate onto the display panel 100, and thus, a manufacturing cost and complexity of the display device 10 may be relatively reduced.

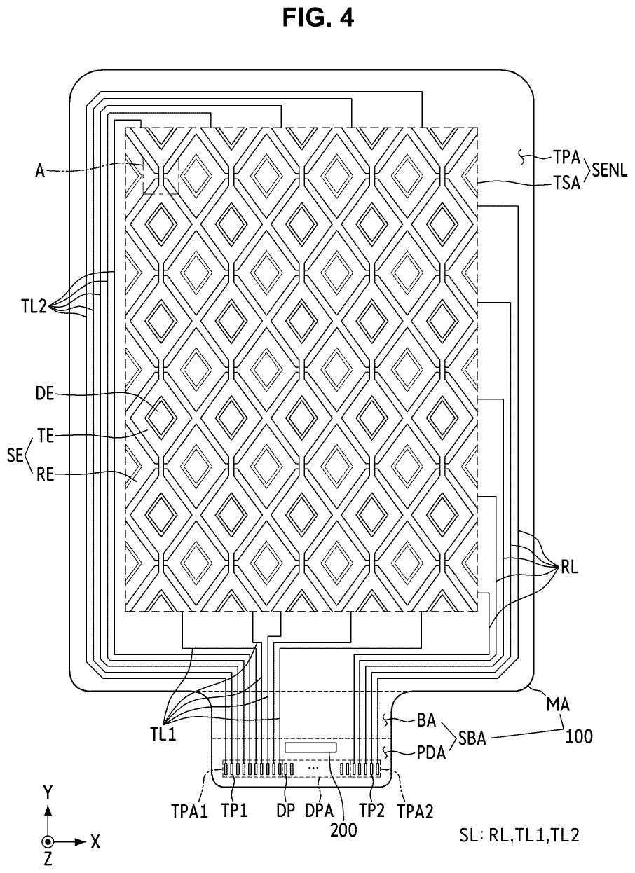

FIG. 4 is a layout view illustrating the touch sensing layer of FIG. 3.

It is mainly described in FIG. 4 that sensor electrodes SE of the touch sensing layer SENL include two types of electrodes, for example, driving electrodes TE and sensing electrodes RE, and are driven in a mutual capacitance manner that senses a voltage charged in the mutual capacitance through the sensing electrodes RE after applying the driving signal to the driving electrodes TE, but embodiments according to the present disclosure are not limited thereto.

In FIG. 4, for convenience of explanation, only the driving electrodes TE, the sensing electrodes RE, dummy patterns DE, sensor lines TL1, TL2, and RL, and sensor pads TP1 and TP2 have been illustrated.

Referring to FIG. 4, the touch sensing layer SENL includes a touch sensor area TSA for sensing a user's touch and a touch peripheral area TPA arranged around the touch sensor area TSA. The touch sensor area TSA may overlap the display area DA of FIGS. 1 to 3, and the touch peripheral area TPA may overlap the non-display area NDA of FIGS. 1 to 3.

The touch sensor area TSA includes the driving electrodes TE, the sensing electrodes RE, and the dummy patterns DE. The driving electrodes TE and the sensing electrodes RE may be electrodes for forming mutual capacitance to sense a touch of an object or a person.

The sensing electrodes RE may be arranged in parallel in the first direction (X-axis direction) and the second direction (Y-axis direction). The sensing electrodes RE may be electrically connected to each other in the first direction (X-axis direction). The sensing electrodes RE adjacent to each other in the first direction (X-axis direction) may be connected to each other. The sensing electrodes RE adjacent to each other in the second direction (Y-axis direction) may be electrically separated from each other.

The driving electrodes TE may be arranged in parallel in the first direction (X-axis direction) and the second direction (Y-axis direction). The driving electrodes TE adjacent to each other in the first direction (X-axis direction) may be electrically separated from each other. The driving electrodes TE may be electrically connected to each other in the second direction (Y-axis direction). For example, the driving electrodes TE adjacent to each other in the second direction DR2 (Y-axis direction) may be connected to each other through a connection electrode BE as illustrated in FIG. 5.

Each of the dummy patterns DE may be surrounded by the driving electrode TE or the sensing electrode RE. Each of the dummy patterns DE may be electrically separated from the driving electrode TE or the sensing electrode RE. Each of the dummy patterns DE may be arranged to be spaced apart from the driving electrode TE or the sensing electrode RE. Each of the dummy patterns DE may be electrically floated.

It is illustrated in FIG. 4 that each of the driving electrodes TE, the sensing electrodes RE, and the dummy patterns DE has a rhombic planar shape, but embodiments according to the present disclosure are not limited thereto. For example, each of the driving electrodes TE, the sensing electrodes RE, and the dummy patterns DE may have a planar shape of a quadrangle other than a rhombus, a polygon other than a quadrangle, a circle, or an oval.

The sensor lines TL1, TL2, and RL may be located in the sensor peripheral area TPA. The sensor lines TL1, TL2, and RL include sensing lines RL connected to the sensing electrodes RE, first driving line TL1 and second driving lines TL2 connected to the driving electrodes TE.

The sensing electrodes RE located on one side of the touch sensor area TSA may be connected to the sensing lines RL in a one-to-one manner. For example, as illustrated in FIG. 4, a sensing electrodes RE located at a right end among the sensing electrodes RE electrically connected to each other in the first direction DR1 (X-axis direction) may be connected to the sensing line RL. The sensing lines RL may be connected to second sensor pads TP2 in a one-to-one manner. Therefore, the touch driving circuit 400 may be electrically connected to the sensing electrodes RE.

The driving electrodes TE located on one side of the touch sensor area TSA may be connected to the first driving lines TL1 in a one-to-one manner, and the driving electrodes TE located on the other side of the touch sensor area TSA may be connected to the second driving lines TL2 in a one-to-one manner. For example, as illustrated in FIG. 4, a driving electrode TE located at a lower end among the driving electrodes TE electrically connected to each other in the second direction DR2 (Y-axis direction) may be connected to the first driving line TL1, and a driving electrode TE located at an upper end among the driving electrodes TE electrically connected to each other in the second direction DR2 (Y-axis direction) may be connected to the second driving line TL2. The second driving lines TL2 may be connected to the driving electrodes TE at an upper side of the touch sensor area TSA via a left outer side of the touch sensor area TSA.

The first driving lines TL1 and the second driving lines TL2 may be connected to first sensor pads TP1 in a one-to-one manner. Therefore, the touch driving circuit 400 may be electrically connected to the driving electrodes TE. Because the driving electrodes TE are connected to the driving lines TL1 and TL2 at both sides of the touch sensor area TSA to receive a touch driving signal, an occurrence of a difference between the touch driving signal applied to the driving electrodes TE located on the lower side of the touch sensor area TSA and the touch driving signal applied to the driving electrodes TE located on the upper side of the touch sensor area TSA due to an RC delay of the touch driving signal may be prevented or relatively reduced.

A first sensor pad area TPA1 in which the first sensor pads TP1 are located may be located on one side of a display pad area DPA in which display pads DP are located. A second sensor pad area TPA2 in which the second sensor pads TP2 are located may be located on the other side of the display pad area DPA. The display pads DP may be electrically connected to data lines of the display panel 100.

The display pad area DPA, the first sensor pad area TPA1, and the second sensor pad area TPA2 may correspond to the pads of the display panel 100 connected to the circuit board 300 illustrated in FIG. 2. The display circuit board 300 may be located on the display pads DP, the first sensor pads TP1, and the second sensor pads TP2. The display pads DP, the first sensor pads TP1, and the second sensor pads TP2 may be electrically connected to the display circuit board 300 using a low-resistance, high-reliability material such as an anisotropic conductive film or SAP. Therefore, the display pads DP, the first sensor pads TP1, and the second sensor pads TP2 may be electrically connected to the touch driving circuit 400 located on the display circuit board 300.

FIG. 5 is an enlarged view of the area A of FIG. 4.

Referring to FIG. 5, the driving electrodes TE and the sensing electrodes RE are located on the same layer, and may thus be spaced apart from each other. That is, a gap may be formed between the driving electrode TE and the sensing electrode RE adjacent to each other.

In addition, the dummy patterns DE may also be located on the same layer as the driving electrodes TE and the sensing electrodes RE. That is, a gap may be formed between the driving electrode TE and the dummy pattern DE adjacent to each other and between the sensing electrode RE and the dummy pattern DE adjacent to each other.

The connection electrodes BE may be located on a different layer from the driving electrodes TE and the sensing electrodes RE. The connection electrode BE may be formed to be bent at least once. It is illustrated in FIG. 5 that the connection electrode BE has a clamp shape (“<” or “>”), but the planar shape of the connection electrode BE is not limited thereto. Because the driving electrodes TE adjacent to each other in the second direction DR2 (Y-axis direction) are connected to each other by a plurality of connection electrodes BE, the driving electrodes TE adjacent to each other in the second direction DR2 (Y-axis direction) may be stably connected to each other even though any one of the connection electrodes BE is disconnected. It is illustrated in FIG. 5 that the driving electrodes TE adjacent to each other are connected to each other by two connection electrodes BE, but the number of connection electrodes BE is not limited thereto.

The connection electrode BE may overlap the driving electrodes TE adjacent to each other in the second direction DR2 (Y-axis direction) in the third direction DR3 (Z-axis direction) which is a thickness direction of the substrate SUB. The connection electrode BE may overlap the sensing electrode RE in the third direction (Z-axis direction). One side of the connection electrode BE may be connected to any one of the driving electrodes TE adjacent to each other in the second direction DR2 (Y-axis direction) through touch contact holes TCNT. The other side of the connection electrode BE may be connected to the other of the driving electrodes TE adjacent to each other in the second direction DR2 (Y-axis direction) through touch contact holes TCNT.

Due to the connection electrodes BE, the driving electrodes TE and the sensing electrodes RE may be electrically separated from each other at the intersection portions therebetween. Therefore, mutual capacitance may be formed between the driving electrodes TE and the sensing electrodes RE.

Each of the driving electrodes TE, the sensing electrodes RE, and the connection electrodes BE may have a planar shape of a mesh structure or a net structure. In addition, each of the dummy patterns DE may have a planar shape of a mesh structure or a net structure. Therefore, each of the driving electrodes TE, the sensing electrodes RE, the connection electrodes BE, and the dummy patterns DE may be arranged to be spaced apart from light emitting portions EA1, EA2, EA3, and EA4 of each of the pixels PX. Therefore, it may be possible to prevent a decrease in luminance of light caused by light emitted from the light emitting portions EA1, EA2, EA3, and EA4 being blocked by the driving electrodes TE, the sensing electrodes RE, the connection electrodes BE, and the dummy patterns DE.

FIG. 6 is an enlarged view of a PX area of FIG. 5.

Referring to FIG. 6, the pixel PX includes a first light emitting portion EA1 emitting light of a first color, a second light emitting portion EA2 emitting light of a second color, a third light emitting portion EA3 emitting light of a third color, and a fourth light emitting portion EA4 emitting the light of the second color. For example, the first color may be red, the second color may be green, and the third color may be blue.

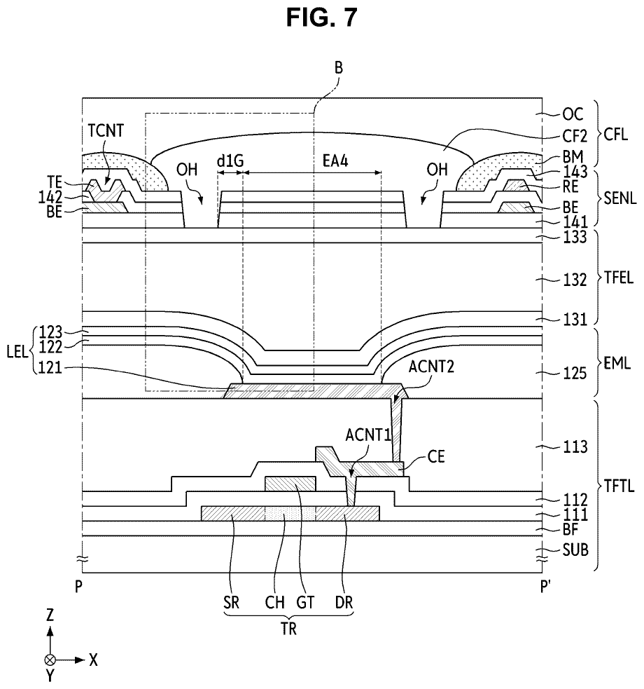

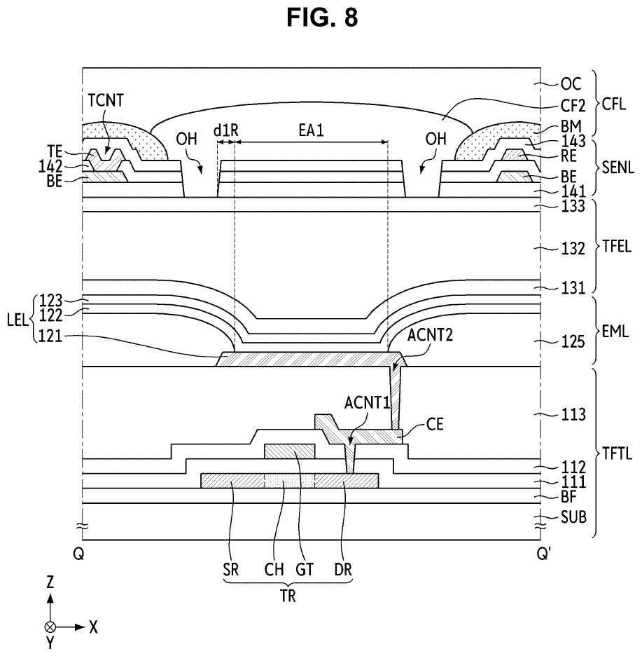

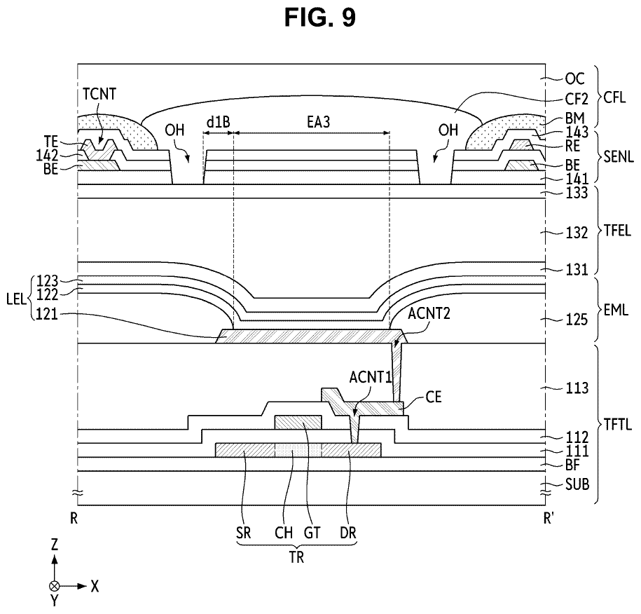

The light emitting portions EA1, EA2, EA3, and EA4 may overlap color filters CF1, CF2, and CF3 corresponding to the light emitted by the light emitting portions EA1, EA2, EA3, and EA4, respectively. For example, the first light emitting portion EA1 emitting the light of the first color may overlap a first color filter (CF1 in FIG. 8) that transmits light of a first wavelength range. The second light emitting portion EA2 and the fourth light emitting portion EA4 emitting the light of the second color may overlap a second color filter (CF2 in FIG. 7) that transmits light of a second wavelength range. The third light emitting portion EA3 emitting the light of the third color may overlap a third color filter (CF3 in FIG. 9) that transmits light of a third wavelength range. The color filters CF1, CF2, and CF3 will be described in more detail later with reference to FIGS. 7 to 9.

The first light emitting portion EA1 and the second light emitting portion EA2 of each of the pixels PX may be adjacent to each other in a fourth direction DR4, and the third light emitting portion EA3 and the fourth light emitting portion EA4 of each of the pixels PX may be adjacent to each other in the fourth direction DR4. The first light emitting portion EA1 and the fourth light emitting portion EA4 of each of the pixels PX may be adjacent to each other in a fifth direction DR5, and the second light emitting portion EA2 and the third light emitting portion EA3 of each of the pixels PX may be adjacent to each other in the fifth direction DR5.

Each of the first light emitting portion EA1, the second light emitting portion EA2, the third light emitting portion EA3, and the fourth light emitting portion EA4 may have a circular planar shape, but is limited thereto. Each of the first light emitting portion EA1, the second light emitting portion EA2, the third light emitting portion EA3, and the fourth light emitting portion EA4 may have a polygonal planar shape such as a rectangle, a rhombus planar shape, or an elliptical planar shape. In addition, it is illustrated in FIG. 6 that the third light emitting portion EA3 has the largest area and the second light emitting portion EA2 and the fourth light emitting portion EA4 have the smallest area, but embodiments according to the present disclosure are not limited thereto.

The second light emitting portions EA2 and the fourth light emitting portions EA4 may be located in odd-numbered rows. The second light emitting portions EA2 and the fourth light emitting portions EA4 may be arranged in parallel in the first direction (X-axis direction) in each of the odd-numbered rows. The second light emitting portions EA2 and the fourth light emitting portions EA4 may be alternately located in each of the odd-numbered rows. The fourth direction DR4 may be a direction between the first direction DR1 (X-axis direction) and the second direction DR2 (Y-axis direction), and may be a direction inclined by 45° with respect to the first direction DR1 (X-axis direction). The fifth direction DR5 may be a direction perpendicular to the fourth direction DR4.

The first light emitting portions EA1 and the third light emitting portions EA3 may be located in even-numbered rows. The first light emitting portions EA1 and the third light emitting portions EA3 may be arranged in parallel in the first direction (X-axis direction) in each of the even-numbered rows. The first light emitting portions EA1 and the third light emitting portions EA3 may be alternately arranged in each of the even-numbered rows.

The second light emitting portions EA2 and the fourth light emitting portions EA4 may be located in odd-numbered columns. The second light emitting portions EA2 and the fourth light emitting portions EA4 may be arranged in parallel in the second direction (Y-axis direction) in each of the odd-numbered columns. The second light emitting portions EA2 and the fourth light emitting portions EA4 may be alternately arranged in each of the odd-numbered columns.

The first light emitting portions EA1 and the third light emitting portions EA3 may be located in even-numbered columns. The first light emitting portions EA1 and the third light emitting portions EA3 may be arranged in parallel in the second direction (Y-axis direction) in each of the even-numbered columns. The first light emitting portions EA1 and the third light emitting portions EA3 may be alternately arranged in each of the even-numbered columns.

Each of the light emitting portions EA1, EA2, EA3, and EA4 may be surrounded by an optical hole OH. In this case, the light emitting portions EA1, EA2, EA3, and EA4 and the optical hole OH may be spaced apart from each other. The optical hole OH may have a donut-shaped planar shape (e.g., a ring shape). The widths of the optical holes OH surrounding the light emitting portions EA1, EA2, EA3, and EA4 may all be formed to be the same. However, embodiments according to the present disclosure are not limited thereto, and the width of the optical hole OH may be differently formed depending on the light emitting portions EA1, EA2, EA3, and EA4.

A black matrix (BM in FIGS. 7, 8, and 9) may be located between the light emitting portions EA1, EA2, EA3, and EA4. The minimum distances dBMR, dBMG, and dBMB between the light emitting portions EA1, EA2, EA3, and EA4 and the black matrix BM may be formed to be different or the same depending on the light emitting portions EA1, EA2, EA3, and EA4.

FIG. 7 is a cross-sectional view of the display panel taken along the line P-P′ of FIG. 6 and FIG. 8 is a cross-sectional view of the display panel taken along the line Q-Q′ of FIG. 6. FIG. 9 is a cross-sectional view of the display panel taken along the line R-R′ of FIG. 6.

Hereinafter, for convenience of explanation, the description will be made based on a cross-section in the first direction (X-axis direction). When the light emitting portions EA1, EA2, EA3, and EA4 and the optical hole OH are formed in a circular shape as illustrated in FIG. 6, the cross section of the display panel 100 cut in the second direction (Y-axis direction), the fourth direction DR4, the fifth direction DR5, or a direction intersecting therewith may be formed into the same shape.

Referring to FIGS. 7 to 9, a buffer film BF may be located on the substrate SUB. The substrate SUB may be made of an insulating material such as a polymer resin. For example, the substrate SUB may be made of polyimide. The substrate SUB may be a flexible substrate that may be bent, folded, rolled, or the like.

The buffer film BF is a film for protecting the transistors of the thin film transistor layer TFTL and a light emitting layer 122 of the light emitting element layer EML from moisture permeating through the substrate SUB, which is vulnerable to moisture permeability. The buffer film BF may include a plurality of inorganic films that are alternately stacked. For example, the buffer film BF may be formed as multiple films in which one or more inorganic films of a silicon nitride layer, a silicon oxynitride layer, a silicon oxide layer, a titanium oxide layer, and an aluminum oxide layer are alternately stacked.

A transistor TR may be located on the buffer film BF. The transistor TR includes a channel CH, a source electrode SR, a drain electrode DR, and a gate electrode GT.

An active layer of the transistor TR may be located on the buffer film BF. The active layer includes a channel CH, a source electrode SR, and a drain electrode DR. The channel CH of the transistor TR includes polycrystalline silicon, single crystal silicon, low-temperature polycrystalline silicon, amorphous silicon, or an oxide semiconductor. The gate electrode GT and the channel CH may overlap in the third direction (Z-axis direction), which is a thickness direction of the substrate SUB. The source electrode SR and the drain electrode DR are regions that do not overlap the gate electrode GT in the third direction (Z-axis direction), and may have conductivity by doping a silicon semiconductor or an oxide semiconductor with ions or impurities.

A gate insulating film 111 may be located on the active layer of the transistor TR. The gate insulating film 111 may be formed as an inorganic film, for example, a silicon nitride layer, a silicon oxynitride layer, a silicon oxide layer, a titanium oxide layer, or an aluminum oxide layer.

The gate electrode GT of the transistor TR may be located on the gate insulating film 111. The gate electrode GT may overlap the channel CH in the third direction (Z-axis direction). The gate electrode GT may be formed of a single layer or multiple layers made of any one of molybdenum (Mo), aluminum (Al), chromium (Cr), gold (Au), titanium (Ti), nickel (Ni), neodymium (Nd), and copper (Cu), or an alloy thereof.

An interlayer insulating film 112 may be located on the gate electrode GT of the transistor TR. The interlayer insulating film 112 may be formed of an inorganic film, for example, a silicon nitride layer, a silicon oxynitride layer, a silicon oxide layer, a titanium oxide layer, or an aluminum oxide layer. The interlayer insulating film 112 may be formed as a plurality of inorganic films.

A first source metal layer may be located on the interlayer insulating film 112. The first source metal layer includes an anode connection electrode CE. The anode connection electrode CE may be connected to the drain electrode DR of the transistor TR through a first contact hole ACNT1 penetrating through the gate insulating film 111 and the interlayer insulating film 112. The anode connection electrode CE may be formed as a single layer or multiple layers made of any one of molybdenum (Mo), aluminum (AI), chromium (Cr), gold (Au), titanium (Ti), nickel (Ni), neodymium (Nd), and copper (Cu), or alloys/combinations thereof.

A protective film 113 may be located on the first source metal layer to planarize a step caused by the transistor TR and protect the transistor TR. The protective film 113 may be formed as an organic film made of an acrylic resin, an epoxy resin, a phenolic resin, a polyamide resin, or a polyimide resin.

A light emitting element layer EML including a light emitting element LEL and a pixel defining film 125 may be located on the protective film 113. Each of the light emitting elements LEL includes a pixel electrode 121, a light emitting layer 122, and a common electrode 123.

For example, a pixel electrode layer may be located on the protective film 113. The pixel electrode layer includes a pixel electrode 121. The pixel electrode 121 may be connected to the anode connection electrode CE through a second contact hole ACNT2 penetrating through the protective film 113. In a top emission structure that emits light in a direction of the common electrode 123 based on the light emitting layer 122, the pixel electrode 121 may be formed of a single layer made of molybdenum (Mo), titanium (Ti), copper (Cu), or aluminum (Al) or be formed in a stacked structure (Ti/Al/Ti) of aluminum and titanium, a stacked structure (ITO/AI/ITO) of aluminum and ITO, an APC alloy, and a stacked structure (ITO/APC/ITO) of an APC alloy and ITO to increase reflectivity. The APC alloy is an alloy of silver (Ag), palladium (Pd), and copper (Cu).

The pixel defining film 125 may be located on a portion of the pixel electrode 121. The pixel defining film 125 serves to define the light emitting portions of the pixels EA1, EA2, EA3, and EA4. The pixel defining film 125 may be formed to expose a portion of the pixel electrode 121 on the protective film 113. The pixel defining film 125 may cover an edge of the pixel electrode 121. The pixel defining film 125 may be formed as an organic film made of an acryl resin, an epoxy resin, a phenolic resin, a polyamide resin, a polyimide resin, or the like.

The light emitting layer 122 may be located on the pixel electrode 121. The light emitting layer 122 may be an organic light emitting layer including an organic material. In this case, the light emitting layer 122 may include a hole transporting layer, an organic light emitting layer, and an electron transporting layer. When a voltage (e.g., a set or predetermined voltage) is applied to the pixel electrode and a cathode voltage is applied to the common electrode through the thin film transistor TR of the thin film transistor layer TFTL, holes and electrons move to the organic light emitting layer 122 through the hole transporting layer and the electron transporting layer, respectively, and are bonded to each other in the organic light emitting layer to emit light. The pixels of the light emitting element layer EML may be located in the display area DA.

The common electrode 123 may be located on the pixel defining film 125 and the light emitting layer 122. The common electrode 123 may be formed to cover the light emitting layer 122. The common electrode 123 may be a common layer commonly formed in the light emitting portions EA1, EA2, EA3, and EA4.

The thin film encapsulation layer TFEL may be located on the light emitting element layer EML. The thin film encapsulation layer TFEL may include a first inorganic encapsulation layer 131 and a second inorganic encapsulation layer 133 that serve to prevent or relatively reduce instances of contaminants such as oxygen or moisture permeating into the light emitting element layer EML. The first inorganic encapsulation layer 131 and the second inorganic encapsulation layer 133 may be a silicon nitride layer, a silicon oxynitride layer, a silicon oxide layer, a titanium oxide layer, or an aluminum oxide layer, but are not limited thereto.

In addition, the thin film encapsulation layer TFEL may include a first organic encapsulation layer 132 that serves to protect the light emitting element layer EML from foreign substances such as dust. The first organic encapsulation layer 132 may be located between the first inorganic encapsulation layer 131 and the second inorganic encapsulation layer 133. The first organic encapsulation film 132 may be made of an acrylic resin, an epoxy resin, a phenolic resin, a polyamide resin, or a polyimide resin, but is not limited thereto.

The thin film encapsulation layer TFEL may be located in both the display area DA and the non-display area NDA. For example, the thin film encapsulation layer TFEL may be arranged to cover the light emitting element layer EML of the display area DA and the non-display area NDA, and cover the thin film transistor layer TFTL of the non-display area NDA.

The touch sensing layer SENL may be located on the thin film encapsulation layer TFEL. The touch sensing layer SENL includes a first touch insulating film 141, a touch connection electrode BE, a second touch insulating film 142, a driving electrode TE, a sensing electrode RE, and a third touch insulating film 143.

The first touch insulating film 141 may be located on the thin film encapsulation layer TFEL. The first touch insulating film may be an inorganic film, for example, a silicon nitride layer, a silicon oxynitride layer, a silicon oxide layer, a titanium oxide layer, or an aluminum oxide layer, but is not limited thereto.

The touch connection electrode BE may be located on the first touch insulating film 141. The touch connection electrode BE may be formed as a single layer or multiple layers made of any one of molybdenum (Mo), aluminum (Al), chromium (Cr), gold (Au), titanium (Ti), nickel (Ni), neodymium (Nd), and copper (Cu), or an alloy thereof.

The second touch insulating film 142 is located on the touch connection electrode BE. The second touch insulating film 142 may be formed as an inorganic film, for example, a silicon nitride layer, a silicon oxynitride layer, a silicon oxide layer, a titanium oxide layer, or an aluminum oxide layer.

The driving electrode TE and the sensing electrode RE may be located on the second touch insulating film 142. In addition, in addition to the driving electrode TE and the sensing electrode RE, the dummy patterns DE, the first driving lines TL1, the second driving lines TL2, and the sensing lines RL illustrated in FIG. 4 may be located on the second touch insulating film 142.

The driving electrode TE and the sensing electrode RE may overlap the touch connection electrode BE in the third direction (Z-axis direction). The driving electrode TE may be connected to the touch connection electrode BE through a touch contact hole TCNT penetrating through the second touch insulating film 142.

The third touch insulating film 143 is formed on the driving electrode TE and the sensing electrode RE. The third touch insulating film 143 may planarize a step formed due to the driving electrode TE, the sensing electrode RE, and the touch connection electrode BE. The third touch insulating film 143 may be formed as an inorganic film, for example, a silicon nitride layer, a silicon oxynitride layer, a silicon oxide layer, a titanium oxide layer, or an aluminum oxide layer.

The color filter layer CFL may be located on the touch sensing layer SENL. The color filter layer CFL may include a color filter, a black matrix BM, and an optical hole OH.

The color filter may include first to third color filters CF1, CF2, and CF3.

The first color filter may transmit light of a first wavelength range and may overlap the first light emitting portion EA1 in the third direction (Z-axis direction). The first light emitting portion EA1 may emit light of a first color corresponding to the light of the first wavelength range. The first wavelength range may be approximately 600 nm to 750 nm.

The first color filter may be arranged to be spaced apart from the driving electrode TE and the sensing electrode RE in the third direction (Z-axis direction). In addition, the first color filter may be arranged to be spaced apart from the touch connection electrode BE in the third direction (Z-axis direction). The first color filter may be arranged to be spaced apart from the touch contact hole TCNT in the third direction (Z-axis direction).

The second color filter may transmit light of a second wavelength range and may overlap the second light emitting portion EA2 and the fourth light emitting portion EA4 in the third direction (Z-axis direction). The second light emitting portion EA2 and the fourth light emitting portion EA4 may emit light of a second color corresponding to the light of the second wavelength range. The second wavelength range may be approximately 480 nm to 560 nm.

The second color filter CF2 may be arranged to be spaced apart from the driving electrode TE and the sensing electrode RE in the third direction (Z-axis direction). In addition, the second color filter CF2 may be arranged to be spaced apart from the touch connection electrode BE in the third direction (Z-axis direction). The second color filter CF2 may be arranged to be spaced apart from the touch contact hole TCNT in the third direction (Z-axis direction).

The third color filter may transmit light of a third wavelength range and may overlap the third light emitting portion EA3 in the third direction (Z-axis direction). The third light emitting portion EA3 may emit light of a third color corresponding to the light of the third wavelength range. The third wavelength range may be approximately 370 nm to 460 nm.

The third color filter may be arranged to be spaced apart from the driving electrode TE and the sensing electrode RE in the third direction (Z-axis direction). In addition, the third color filter may be arranged to be spaced apart from the touch connection electrode BE in the third direction (Z-axis direction). The third color filter may be arranged to be spaced apart from the touch contact hole TCNT in the third direction (Z-axis direction).

Refractive indices of the color filters CF1, CF2, and CF3 may be lower than refractive indices of the first to third inorganic insulating films 141, 142, and 143. Accordingly, light may be refracted at an interface between the first to third inorganic insulating films 141, 142, and 143 and the color filter. For example, light emitted from the light emitting element LEL may be refracted at a large refractive angle on a surface of an optical hole OH adjacent to the pixel defining film. Here, the refractive angle refers to an angle formed by the normal to the surface of the optical hole OH and a light path. As the refractive angle decreases, the light emitted from the light emitting element LEL may travel in the front direction of the display device 10.

The black matrix BM may use a material that blocks the light emitting element LEL from emitting light. The black matrix BM may be formed using a material that absorbs visible light, for example, a resin material including a metal material, a pigment, or a dye. The black matrix BM may prevent or relatively reduce color mixing between the pixels PX by blocking the light from the light emitting element LEL.

The minimum distances dBMR, dBMG, and dBMB between the light emitting portions EA1, EA2, EA3, and EA4 and the black matrix BM in the first direction (X-axis direction) (i.e., the minimum distance between the pixel defining film 125 and the black matrix BM adjacent to the pixel defining film 125 in the first direction (X-axis direction)) may vary depending on the light emitting portions EA1, EA2, EA3, and EA4. This is because the refractive index is different depending on the wavelength of light. The light that travels from the light emitting portions EA1, EA2, EA3, and EA4 to the thin film encapsulation layer TFEL may have different refractive indices depending on the wavelength even if the light passes through the same section, and thus the light path thereof may be different. Accordingly, the minimum distances dBMR, dBMG, and dBMB between the light emitting portions EA1, EA2, EA3, and EA4 and the black matrix BM in the first direction (X-axis direction) to maximize the light emitted from the light emitting portions EA1, EA2, EA3, and EA4 may vary depending on the wavelength of the light emitted from the light emitting portions EA1, EA2, EA3, and EA4.

In addition, due to the difference in efficiency depending on the type of light emitting portions EA1, EA2, EA3, and EA4, the sizes of the light emitting portions EA1, EA2, EA3, and EA4 may be different from each other. Accordingly, the minimum distances dBMR, dBMG, and dBMB between the light emitting portions EA1, EA2, EA3, and EA4 and the black matrix BM in the first direction (X-axis direction) may be adjusted in proportion to the sizes of the light emitting portions EA1, EA2, EA3, and EA4.

For example, the minimum distance dBMG between the second light emitting portion EA2 or the fourth light emitting portion EA4 emitting the light of the second color and the black matrix BM in the first direction (X-axis direction) may be 5.72 μm.

As illustrated in FIG. 7, because the color filters CF are located on the black matrix BM, the color filters CF may be formed after the black matrix BM is formed on the touch sensing layer SENL.

The optical hole OH may penetrate through the touch sensing layer SENL. That is, the optical hole OH is a hole that penetrates through the first inorganic insulating film 141, the second inorganic insulating film 142, and the third inorganic insulating film 143.

The optical hole OH may be filled with a color filter. The color filters filled in the optical hole OH may be matched to the color of the light emitted from the light emitting portions EA1, EA2, EA3, and EA4. The optical hole OH formed between the first light emitting portion EA1 and the first color filter CF1 may be filled with the first color filter CF1. The optical hole OH formed between the second light emitting portion EA2 or the fourth light emitting portion EA4 and the second color filter CF2 may be filled with the second color filter CF2. The optical hole OH formed between the third light emitting portion EA3 and the third color filter CF3 may be filled with the third color filter CF3.

According to some embodiments of the present disclosure, the optical holes OH may be arranged to be spaced apart from the black matrix BM.

The minimum distance (d1G in FIG. 7, d1R in FIGS. 8, and d1B in FIG. 9) from the pixel defining film 125 to the optical hole OH adjacent to the pixel defining film in the first direction (X-axis direction) in plan view may be determined depending on the refractive index of the color filters and the refractive index between the first to third inorganic insulating films 141, 142, and 143.

The refractive index of the first to third inorganic insulating films 141, 142, and 143 may be greater than the refractive index of the color filter. Accordingly, refraction may occur on a surface of the optical hole OH where the color filters and the first to third inorganic insulating films 141, 142, and 143 come into contact, so that the refractive angle increases.

For example, a refractive index of the first color filter CF1 of FIG. 8 may be greater than a refractive index of the second color filter CF2 of FIG. 7. Accordingly, a refractive index difference between the first color filter CF1 of FIG. 8 and the first to third inorganic insulating films 141, 142, and 143 may be smaller than a refractive index difference between the second color filter CF2 of FIG. 7 and the first to third inorganic insulating films 141, 142, and 143. Therefore, the refractive angle from the surface of the optical hole OH of FIG. 8 toward the color filter may be smaller than the refractive angle from the surface of the optical hole OH of FIG. 7 toward the color filter.

In addition, the minimum distance d1R from the pixel defining film 125 of FIG. 8 to the optical hole OH adjacent to the pixel defining film 125 in the first direction (X-axis direction) may be shorter than the minimum distance d1G from the pixel defining film 125 of FIG. 7 to the optical hole OH adjacent to the pixel defining film 125 in the first direction (X-axis direction). This is to secure a distance between an inner peripheral surface of the optical hole OH adjacent to the pixel defining film 125 and the black matrix BM, as the refractive angle of light traveling from the optical hole OH of FIG. 8 to the color filter becomes smaller than the refractive angle of light traveling from the optical hole OH of FIG. 7 to the color filter. In other words, when the first color filter CF1 of FIG. 8 is applied, the distance between the inner peripheral surface of the optical hole OH and the black matrix BM may be longer than when the second color filter CF2 of FIG. 7 is applied. Accordingly, even if the refractive angle at the surface of the optical hole OH is small, the light that was blocked by the black matrix BM may be emitted in the front direction of the display device 10.

Meanwhile, a refractive index of the third color filter CF3 of FIG. 9 may be greater than the refractive index of the second color filter CF2 of FIG. 7. Accordingly, a refractive index difference between the third color filter CF3 of FIG. 9 and the first to third inorganic insulating films 141, 142, and 143 may be greater than the refractive index difference between the second color filter CF2 of FIG. 7 and the first to third inorganic insulating films 141, 142, and 143. Therefore, the refractive angle from the surface of the optical hole OH of FIG. 9 toward the color filter may be greater than the refractive angle from the surface of the optical hole OH of FIG. 7 toward the color filter.

In addition, the minimum distance d1B from the pixel defining film 125 of FIG. 9 to the optical hole OH adjacent to the pixel defining film 125 in the first direction (X-axis direction) may be greater than the minimum distance d1G from the pixel defining film 125 of FIG. 7 to the optical hole OH adjacent to the pixel defining film 125 in the first direction (X-axis direction). This is to emit light traveling near the black matrix BM in the front direction of the display device 10, as the refractive angle of light traveling from the optical hole OH of FIG. 9 to the color filter becomes larger than the refractive angle of light traveling from the optical hole OH of FIG. 7 to the color filter. In other words, when the third color filter CF3 of FIG. 9 is applied, the distance between the optical hole OH adjacent to the pixel defining film 125 and the black matrix BM may be closer than when the second color filter CF2 of FIG. 7 is applied. Accordingly, the light traveling close to the black matrix BM may be emitted in the front direction of the display device 10.

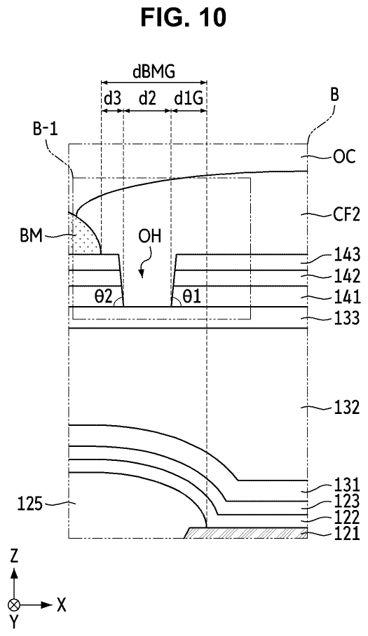

FIG. 10 is an enlarged view of the area B of FIG. 7. Hereinafter, for convenience for explanation, the description will be made based on the fourth light emitting portion EA4 that emits light of the second color and the second color filter CF2 that transmits light of the second wavelength range.

Referring to FIG. 10, the minimum distance d1G between the pixel defining film 125 and the optical hole OH in the first direction (X-axis direction) or the second direction (Y-axis direction) may be shorter than a width d2 of the optical hole OH in the first direction (X-axis direction) or the second direction (Y-axis direction). Through this, a light emission efficiency of light emitted to the outside of the display device 10 may be increased. Hereinafter, for convenience of explanation, the description will be made based on the first direction (X-axis direction).

When the minimum distance d1G between the pixel defining film 125 and the optical hole OH in the first direction (X-axis direction) is greater than the width d2 of the optical hole OH in the first direction (X-axis direction), the inner peripheral surface of the optical hole OH is arranged to be adjacent to the black matrix BM. In this case, as the light refracted at the interface due to the refractive index difference between the first to third inorganic insulating films 141, 142, and 143 and the second color filter CF2 in the optical hole OH travels to the black matrix BM, the light emission efficiency of light emitted to the outside of the display device 10 may be relatively reduced.

In addition, the minimum distance dBMG from the pixel defining film 125 to the black matrix BM adjacent to the pixel defining film 125 in the first direction (X-axis direction) may be greater than the width d2 of the optical hole OH. The minimum distance dBMG from the pixel defining film 125 to the black matrix BM adjacent to the pixel defining film 125 in the first direction (X-axis direction) may be greater than the minimum distance d1G between the optical hole OH and the pixel defining film 125 in the first direction (X-axis direction). In addition, the width d2 of the optical hole OH in the first direction (X-axis direction) may be greater than the minimum distance d1G between the optical hole OH and the pixel defining film 125 in the first direction (X-axis direction). Through such a structure, the light refracted at the inner peripheral surface of the optical hole OH may be emitted to the outside of the display device 10 through the color filters instead of traveling toward the black matrix BM. Therefore, luminance of the display device 10 may increase.

According to some embodiments of the present disclosure, the minimum distance dBMG from the pixel defining film 125 to the black matrix BM adjacent to the pixel defining film 125 in the first direction (X-axis direction) may be equal to the sum of the minimum distance d3 between the optical hole OH and the black matrix BM in the first direction (X-axis direction), the width d2 of the optical hole OH in the first direction (X-axis direction), and the minimum distance d1G between the optical hole OH and the pixel defining film 125 in the first direction (X-axis direction).

For example, the minimum distance dBMG from the pixel defining film 125 to the black matrix BM adjacent to the pixel defining film 125 in the first direction (X-axis direction) may be 5.72 μm. In this case, the width d2 of the optical hole OH in the first direction (X-axis direction) may be 5 μm. In addition, the minimum distance d1G between the optical hole (OH) and the pixel defining film 125 in the first direction (X-axis direction) may be 0.3 μm to 0.72 μm. In this case, the amount of light emitted in the front direction of the display device 10 may be changed depending on the minimum distance d1G between the optical hole (OH) and the pixel defining film 125 in the first direction (X-axis direction). When the minimum distance d1G between the optical hole (OH) and the pixel defining film 125 in the first direction (X-axis direction) is shorter than 0.3 μm, the light traveling in the front direction of the display device 10 may be refracted, causing the luminance at the front of the display device 10 to decrease. However, embodiments according to the present disclosure are not limited to the above-mentioned numerical values, and may be modified and implemented while maintaining the size relationship between the distances d1G, d2, d3, and dBMG.

An angle θ1 formed between a lower surface of the first inorganic insulating film 141 and the inner peripheral surface of the optical hole OH may be 50° to 70°. The amount of light emitted in the front direction of the display device 10 may be changed depending on the angle θ1 formed between the lower surface of the first inorganic insulating film 141 and the inner peripheral surface of the optical hole OH. When the angle θ1 formed between the lower surface of the first inorganic insulating film 141 and the inner peripheral surface of the optical hole OH is less than 50°, the light refracted at the inner peripheral surface of the optical hole OH may be directed toward the side surface of the display device 10. When the angle θ1 formed between the lower surface of the first inorganic insulating film 141 and the inner peripheral surface of the optical hole OH exceeds 70°, the light refracted at the inner peripheral surface of the optical hole OH may be directed toward the black matrix BM. Therefore, when the angle θ1 formed between the lower surface of the first inorganic insulating film 141 and the inner peripheral surface of the optical hole OH is 50° to 70°, the amount of light directed in the front direction of the display device 10 may be maximized.

On the other hand, an angle θ2 formed between the lower surface of the first inorganic insulating film 141 and an outer peripheral surface of the optical hole OH and the minimum distance d3 between the optical hole OH and the black matrix BM in the first direction (X-axis direction) may not affect the amount of light directed in the front direction of the display device 10. This is because light refracted at the outer peripheral surface of the optical hole OH is blocked by the black matrix BM and is not emitted in the front direction of the display device 10.

For convenience of explanation, FIG. 10 illustrates the minimum distance d1G between the optical hole OH and the pixel defining film 125 in the first direction (X-axis direction), the width d2 of the optical hole OH in the first direction (X-axis direction), the minimum distance d3 between the optical hole OH and the black matrix BM in the first direction (X-axis direction), and the minimum distance dBMG between the pixel defining film 125 and the black matrix BM adjacent to the pixel defining film 125 in the first direction (X-axis direction), but they may be formed identically in any straight line direction intersecting the second direction (Y-axis direction) or the first direction (X-axis direction) and the second direction (Y-axis direction).

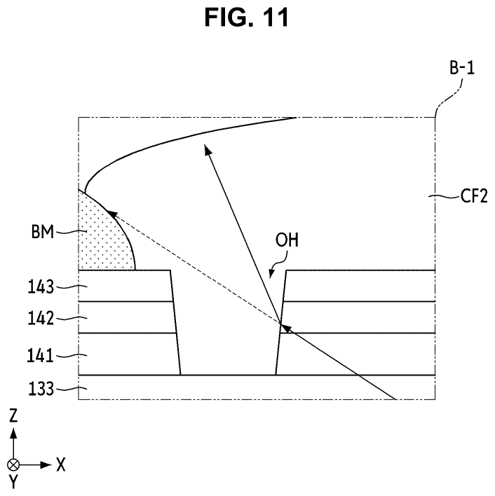

FIG. 11 is an enlarged view of the area B-1 of FIG. 10.

Referring to FIG. 11, light passing through the second inorganic encapsulation layer 133, the first inorganic insulating film 141, and the second inorganic insulating film 142 may be refracted as it travels from the inner peripheral surface of the optical hole OH to the second color filter CF2. In this case, the refractive index of the first inorganic insulating film 141, the refractive index of the second inorganic insulating film 142, and the refractive index of the third inorganic insulating film 143 may be greater than the refractive index of the second color filter CF2. Accordingly, the light traveling from the inner peripheral surface of the optical hole OH to the second color filter CF2 may be refracted in a direction in which the refractive angle increases (i.e., in the front direction of the display device 10). Through this, the light that was previously blocked by the black matrix BM may be emitted to the outside of the display device 10, thereby increasing the luminance of the display device 10.

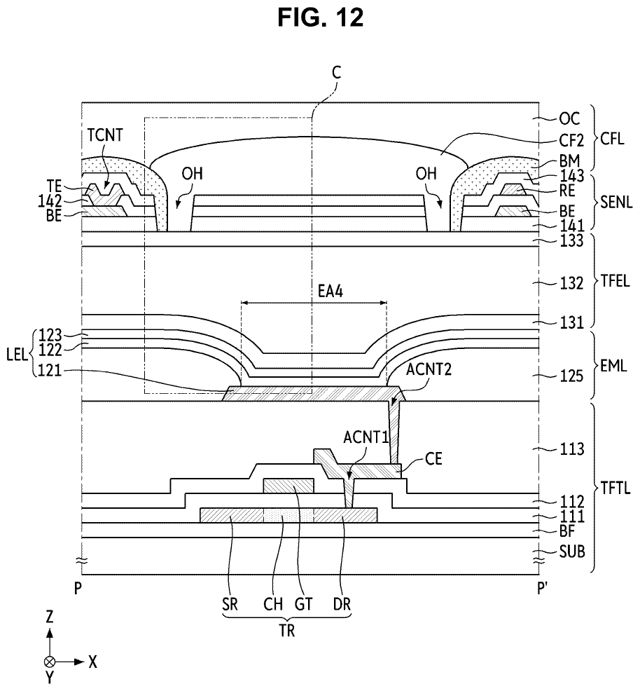

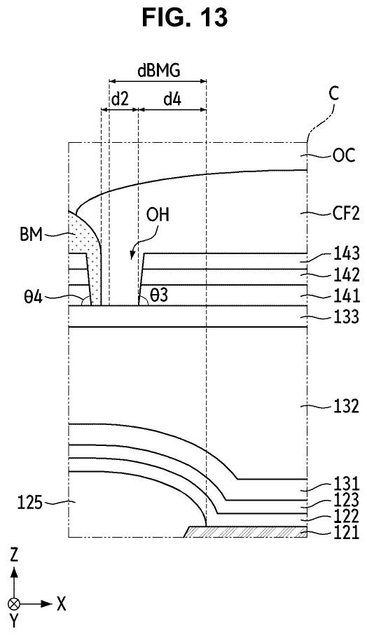

FIG. 12 is a cross-sectional view of the display panel taken along the line P-P′ of FIG. 6 and FIG. 13 is an enlarged view of the area C of FIG. 12. Description of some parts that overlap the contents described above may be omitted or briefly described, and the differences will be mainly described.

Referring to FIG. 12, as described above, the color filters filled in the optical hole OH may be matched to the color of the light emitted from the light emitting portions EA1, EA2, EA3, and EA4. FIG. 12 illustrates an example of the fourth light emitting portion EA4 that emits light of the second color and the second color filter CF2 that transmits light of the second wavelength range.

Referring to FIG. 12, a portion of the optical hole OH may be filled with the color filter, and the remainder of the optical hole OH may be filled with the black matrix BM.

For example, referring to FIG. 13, the minimum distance dBMG from the pixel defining film 125 to the black matrix BM adjacent to the pixel defining film 125 in the first direction (X-axis direction) may be formed in the same manner as in FIG. 10 described above. That is, the minimum distance dBMG from the pixel defining film 125 to the black matrix BM adjacent to the pixel defining film 125 in the first direction (X-axis direction) may be greater than the minimum distance d1G between the optical hole OH and the pixel defining film 125 in the first direction (X-axis direction), and may vary depending on the wavelength of light emitted from the light emitting element LEL. For example, the minimum distance dBMG from the pixel defining film 125 to the black matrix BM adjacent to the pixel defining film 125 in the first direction (X-axis direction) may be 5.72 μm.

On the other hand, a minimum distance d4 between the pixel defining film 125 and the optical hole OH adjacent to the pixel defining film 125 in the first direction (X-axis direction) may be greater than the minimum distance d1 between the pixel defining film 125 of FIG. 10 and the optical hole OH adjacent to the pixel defining film 125 in the first direction (X-axis direction). Even in this case, the minimum distance d4 between the pixel defining film 125 and the optical hole OH adjacent to the pixel defining film 125 in the first direction (X-axis direction) may be shorter than the width d2 of the optical hole OH in the first direction (X-axis direction). For example, the minimum distance d4 between the pixel defining film 125 and the optical hole OH adjacent to the pixel defining film 125 in the first direction (X-axis direction) may be 0.72 μm to 4 μm. When the minimum distance d4 between the pixel defining film 125 and the optical hole OH adjacent to the pixel defining film 125 in the first direction (X-axis direction) is greater than 4 μm, the light refracted at the inner peripheral surface of the optical hole OH may travel to the black matrix BM, thereby relatively reducing the light emission efficiency of the display device 10.

Meanwhile, the width d2 of the optical hole OH in the first direction (X-axis direction) may be formed in the same manner as in FIG. 10 described above. For example, the width d2 of the optical hole OH in the first direction (X-axis direction) may be 5 μm. However, embodiments according to the present disclosure are not limited thereto.

Accordingly, the sum of the minimum distance d4 between the pixel defining film 125 and the optical hole OH adjacent to the pixel defining film 125 in the first direction (X-axis direction) and the width d2 of the optical hole OH in the first direction (X-axis direction) may be greater than the minimum distance dBMG from the pixel defining film 125 to the black matrix BM adjacent to the pixel defining film 125 in the first direction (X-axis direction).

Meanwhile, an angle θ3 formed between the lower surface of the first inorganic insulating film 141 and the inner peripheral surface of the optical hole OH may be formed in the same manner as in FIG. 10. Accordingly, the angle θ3 formed between the lower surface of the first inorganic insulating film 141 and the inner peripheral surface of the optical hole OH may be formed between 50° and 70°, and the light refracted at the inner peripheral surface of the optical hole OH may be emitted in the front direction of the display device 10.

An angle θ4 formed between the lower surface of the first inorganic insulating film 141 and the outer peripheral surface of the optical hole OH may not affect the amount of light emitted in the front direction of the display device 10 as in FIG. 10.

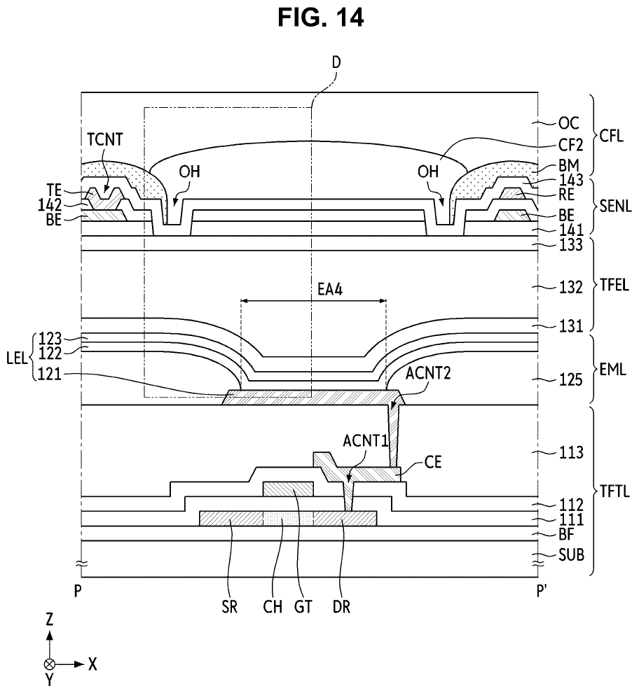

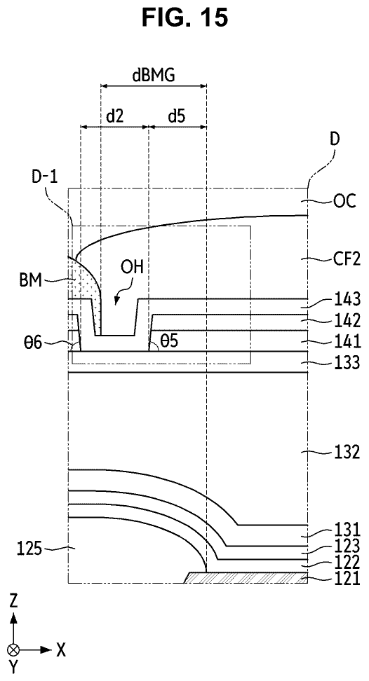

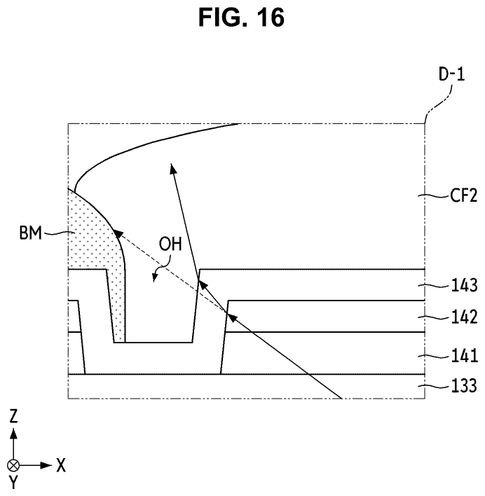

FIG. 14 is a cross-sectional view of the display panel taken along the line P-P′ of FIG. 6 and FIG. 15 is an enlarged view of the area D of FIG. 14. FIG. 16 is an enlarged view of D-1 area of FIG. 15. Description of some parts that overlap the contents described above may be omitted or briefly described, and the differences will be mainly described.

As described above, the color filters filled in the optical hole OH may be matched to the color of the light emitted from the light emitting portions EA1, EA2, EA3, and EA4. FIG. 12 illustrates an example of the fourth light emitting portion EA4 that emits light of the second color and the second color filter CF2 that transmits light of the second wavelength range.

Referring to FIG. 14, a portion of the third inorganic insulating film 143 may be located on the optical hole OH. The remaining portion of the optical hole OH, i.e., the third inorganic insulating film 143 located in the optical hole OH, may be filled with the second color filter CF2 and the black matrix BM.

For example, referring to FIG. 15, the minimum distance dBMG from the pixel defining film 125 to the black matrix BM adjacent to the pixel defining film 125 in the first direction (X-axis direction) may be formed in the same manner as in FIGS. 10 and 13. That is, the minimum distance dBMG from the pixel defining film 125 to the black matrix BM adjacent to the pixel defining film 125 in the first direction (X-axis direction) may be greater than the width d2 of the optical hole OH. For example, the minimum distance dBMG from the pixel defining film 125 to the black matrix BM adjacent to the pixel defining film 125 in the first direction (X-axis direction) may be 5.72 μm.

A minimum distance d5 from the pixel defining film 125 to the optical hole OH adjacent to the pixel defining film 125 in the first direction (X-axis direction) may be formed in the similar manner as in FIG. 10 or 13. In other words, the minimum distance d5 from the pixel defining film 125 to the optical hole OH adjacent to the pixel defining film 125 in the first direction (X-axis direction) may be shorter than the minimum distance dBMG from the pixel defining film 125 to the black matrix BM adjacent to the pixel defining film 125 in the first direction (X-axis direction). In addition, the minimum distance d5 from the pixel defining film 125 to the optical hole OH adjacent to the pixel defining film 125 in the first direction (X-axis direction) may be shorter than the width d2 of the optical hole OH in the first direction (X-axis direction).

The width d2 of the optical hole OH in the first direction (X-axis direction) may be formed in the same manner as in FIGS. 10 and 13. For example, the width d2 of the optical hole OH in the first direction (X-axis direction) may be 5 μm.

Accordingly, the minimum distance dBMG from the pixel defining film 125 to the black matrix BM adjacent to the pixel defining film 125 in the first direction (X-axis direction) may be shorter than the sum of the minimum distance d5 from the pixel defining film 125 to the optical hole OH adjacent to the pixel defining film 125 in the first direction (X-axis direction) and the width d2 of the optical hole OH in the first direction (X-axis direction).

Meanwhile, a thickness t1 of the third inorganic insulating film 143 may be shorter than half the width d2 of the optical hole OH in the first direction (X-axis direction). This is to prevent or relatively reduce instances of a phenomenon in which light refracted at the third inorganic insulating film 143 does not travel to the color filters but is incident into the third inorganic insulating film 143 again.

Meanwhile, an angle θ5 formed between the lower surface of the first inorganic insulating film 141 and the inner peripheral surface of the optical hole OH may be formed in the same manner as in FIGS. 10 and 13. Accordingly, the angle θ5 formed between the lower surface of the first inorganic insulating film 141 and the inner peripheral surface of the optical hole OH may be formed between 50° and 70°, and the light refracted at the side surface of the optical hole OH may be emitted in the front direction of the display device 10.

An angle θ6 formed between the lower surface of the first inorganic insulating film 141 and the other side surface of the optical hole OH may not affect the amount of light emitted in the front direction of the display device 10 in the same manner as in FIGS. 10 and 13.

For example, referring to FIG. 16, the refractive index of the third inorganic insulating film 143 may be lower than the refractive index of the first inorganic insulating film 141 and the refractive index of the second inorganic insulating film 142. Accordingly, light passing through the second inorganic encapsulation layer 133, the first inorganic insulating film 141, and the second inorganic insulating film 142 may be refracted in a direction in which the refractive angle increases when it is incident into the third inorganic insulating film 143.

In addition, the refractive index of the third inorganic insulating film 143 may be lower than that of the color filter. Accordingly, light passing through the third inorganic insulating film 143 may be refracted in a direction in which the refractive angle increases when it is incident into the second color filter CF2.

As the third inorganic insulating film 143 is located on the optical hole OH, light generated from the light emitting element LEL may travel toward the black matrix BM and be refracted twice to be emitted to the outside of the display device 10 according to some embodiments. Through this, the light that was previously blocked by the black matrix BM and could not be emitted may be emitted to the outside of the display device 10, thereby increasing the luminance of the display device 10.

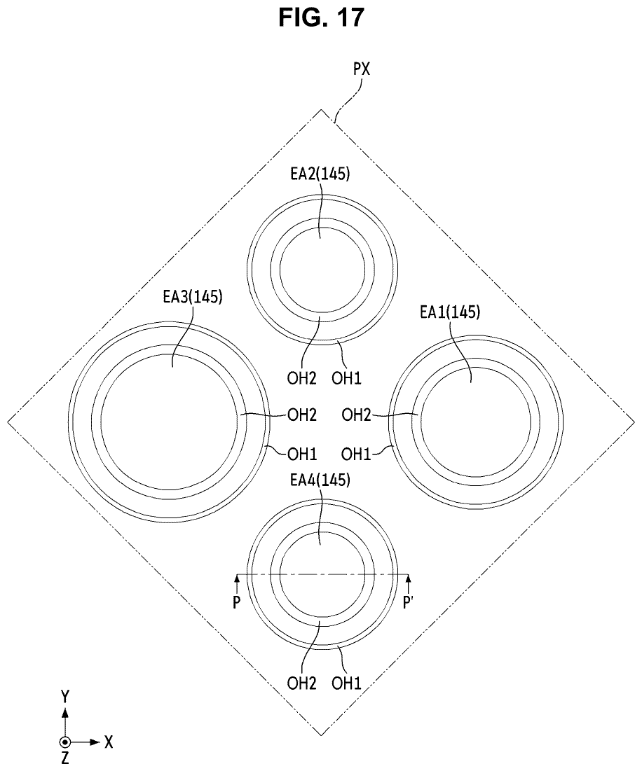

FIG. 17 is a layout view illustrating another example of the light emitting area of FIG. 5.

Embodiments illustrated in FIG. 17 differ from the embodiments of FIG. 6 in that a second optical hole OH2 located outside the first optical hole OH1 is added.

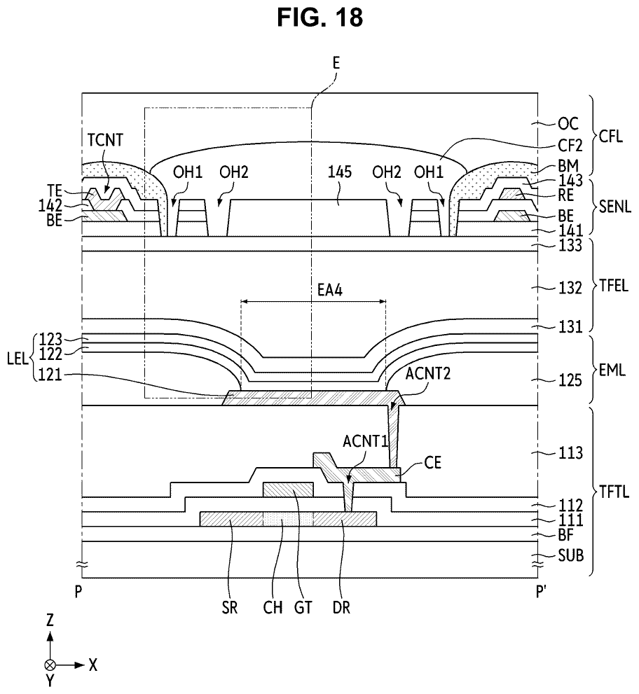

Referring to FIG. 17, each of the light emitting portions EA1, EA2, EA3, and EA4 may be surrounded by a second optical hole OH2. An inner circumference of the second optical hole OH2 may overlap a circumference of the pixel defining film (125 in FIG. 18) defining each of the light emitting portions EA1, EA2, EA3, and EA4.

Alternatively, when the inner circumference of the second optical hole OH2 does not overlap the circumference of the pixel defining film 125, the inner circumference of the second optical hole OH2 may be smaller than the circumference of the pixel defining film 125. In this case, a portion of the second optical hole OH2 may overlap each of the light emitting portions EA1, EA2, EA3, and EA4.

In addition, the second optical hole OH2 may be surrounded by the first optical hole OH1. The second optical hole OH2 and the first optical hole OH1 may not be in contact with each other. Therefore, an outer circumference of the second optical hole OH2 may be smaller than an inner circumference of the first optical hole OH1. Although the drawing illustrates the first optical hole OH1 and the second optical hole OH2 as having a donut-shaped planar shape, the first and second optical holes OH1 and OH2 may also be formed in other shapes, such as a rectangular band or a polygonal band.

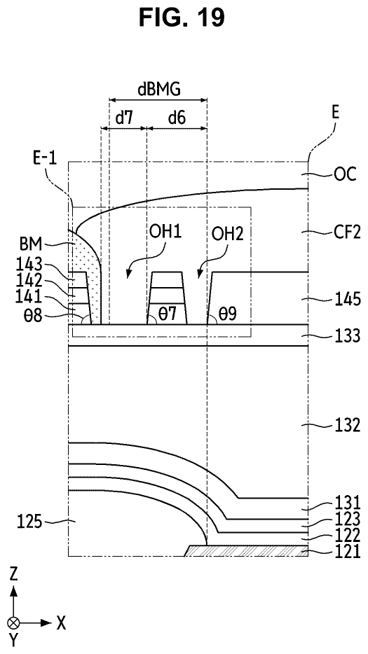

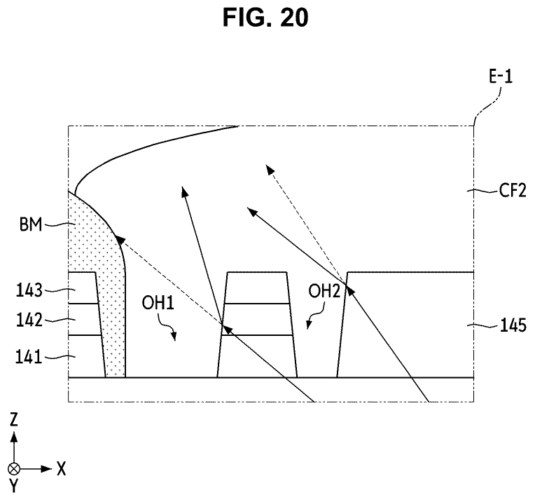

FIG. 18 is a cross-sectional view of the display panel taken along the line P-P′ of FIG. 6. FIG. 19 is an enlarged view of the area E of FIG. 18 and FIG. 20 is an enlarged view of the area E-1 of FIG. 19. Some description of parts that overlap the contents described above may be omitted or briefly described, and the differences will be mainly described.

As described above, the color filters filled in the first optical hole OH1 and the second optical hole OH2 may be matched to the color of the light emitted from the light emitting portions EA1, EA2, EA3, and EA4. FIGS. 18 to 20 illustrate an example of the fourth light emitting portion EA4 that emits light of the second color and the second color filter CF2 that transmits light of the second wavelength range.

Referring to FIG. 18, the touch sensing layer SENL may include an organic film 145. The organic film 145 may be located between the thin film encapsulation layer TFEL and the color filter. The organic film 145 may be arranged to be spaced apart from the first to third inorganic insulating films 141, 142, and 143. The organic film 145 may overlap the fourth light emitting portion EA4 in the third direction (Z-axis direction). In plan view, the organic film 145 may be surrounded by the second optical hole OH2.

The second optical hole OH2 may be located between the organic film 145 and the first inorganic insulating film 141, between the organic film 145 and the second inorganic insulating film 142, and between the organic film 145 and the third inorganic insulating film 143.

A lower surface of the organic film 145 may be longer than an upper surface of the organic film 145, and a side surface of the organic film 145 may be formed to flatly connect the upper and lower surfaces of the organic film 145. The side surface of the organic film 145 may define an inner peripheral surface of the second optical hole OH2.

The upper and side surfaces of the organic film 145 may be in contact with the color filter. In addition, a refractive index of the organic film 145 may be different from that of the color filter. Accordingly, light traveling from the upper and side surfaces of the organic film 145 to the color filters may be refracted at an interface.

Referring to FIG. 19, the minimum distance dBMG between the pixel defining film 125 and the black matrix BM adjacent to the pixel defining film 125 in the first direction (X-axis direction) may be formed in the same manner as in FIGS. 10, 13, and 15. That is, the minimum distance dBMG from the pixel defining film 125 to the black matrix BM adjacent to the pixel defining film 125 in the first direction (X-axis direction) may be greater than the width d2 of the optical hole OH. For example, the minimum distance dBMG from the pixel defining film 125 to the black matrix BM adjacent to the pixel defining film 125 in the first direction (X-axis direction) may be 5.72 μm.

A width d7 of the first optical hole OH1 in the first direction (X-axis direction) may be formed in the same manner as in FIGS. 10, 13, and 15, or may be formed to be smaller than in FIGS. 10, 13, and 15. For example, the width d7 of the optical hole OH in the first direction (X-axis direction) may be 5 μm.

A minimum distance d6 between the pixel defining film 125 and the first optical hole OH1 adjacent to the pixel defining film 125 in the first direction (X-axis direction) may be formed in the similar manner as in FIG. 10 or 13. In other words, the minimum distance d6 between the optical hole OH and the pixel defining film 125 in the first direction (X-axis direction) may be shorter than the minimum distance dBMG from the pixel defining film 125 to the black matrix BM adjacent to the pixel defining film 125 in the first direction (X-axis direction).

The minimum distance dBMG between the pixel defining film 125 and the black matrix BM adjacent to the pixel defining film 125 in the first direction (X-axis direction) may be shorter than the sum of a width d7 of the first optical hole OH1 in the first direction (X-axis direction) and the minimum distance d6 between the pixel defining film 125 and the first optical hole OH1 adjacent to the pixel defining film 125 in the first direction (X-axis direction).

It is illustrated in the drawing that the inner peripheral surface of the second optical hole OH2 and the boundary of the thin film encapsulation layer TFEL are aligned with the circumference of the pixel defining film 125, but embodiments according to the present disclosure are not limited thereto. The width of the organic film 145 may be smaller than that illustrated in the drawing. In this case, the inner peripheral surface of the second optical hole OH2 and the boundary of the thin film encapsulation layer TFEL may not be aligned with the circumference of the pixel defining film 125.

Meanwhile, an angle θ7 formed between the lower surface of the first inorganic insulating film 141 and an inner peripheral surface of the first optical hole OH1 may be formed in the same manner as in FIGS. 10, 13, and 15. Accordingly, the angle θ7 formed between the lower surface of the first inorganic insulating film 141 and the inner peripheral surface of the first optical hole OH1 may be formed between 50° and 70°, and the light refracted at the inner peripheral surface of the first optical hole OH1 may be emitted in the front direction of the display device 10.

An angle θ8 formed between the lower surface of the first inorganic insulating film 141 and an outer peripheral surface of the first optical hole OH1 may not affect the amount of light emitted in the front direction of the display device 10 as in FIGS. 10, 13, and 15.

An angle θ9 formed between the lower surface of the first inorganic insulating film 141 and an inner peripheral surface of the second optical hole OH2 may be formed in the same manner as the angle θ7 formed between the lower surface of the first inorganic insulating film 141 and the inner peripheral surface of the first optical hole OH1. Accordingly, the angle θ9 formed between the lower surface of the first inorganic insulating film 141 and the inner peripheral surface of the second optical hole OH2 may be formed between 50° and 70°, and the light refracted at the inner peripheral surface of the second optical hole OH2 may be emitted in the front direction of the display device 10.

Referring to FIG. 20, a refractive index of the organic film 145 may be lower than the refractive index of the color filter. According to some embodiments, the refractive index of the first to third inorganic insulating films 141, 142, and 143 may be greater than the refractive index of the color filter. Accordingly, the refractive index of the inorganic film 145 may be lower than the refractive index of the first to third inorganic insulating films 141, 142, and 143.

Accordingly, light passing through the organic film 145 may be refracted in a direction in which the refractive angle decreases when it is incident into the second color filter CF2. That is, the light passing through the organic film 145 may be emitted in a side direction of the display device 10. Through this, the amount of light directed in the side direction of the display device 10 may be increased, thereby relatively improving the luminance of the display device 10 when observed from the side compared to the front.

It should be understood, however, that the aspects and features of embodiments of the present disclosure are not restricted to those set forth herein. The above and other aspects of the present disclosure will become more apparent to one of ordinary skill in the art to which the present disclosure pertains by referencing the claims, with equivalents thereof to be included therein.

What is claimed is:

1. A display device comprising:
a substrate;
a pixel electrode on one surface of the substrate;
a pixel defining film exposing a portion of the pixel electrode and defining a light emitting area;
a light emitting layer on the pixel electrode in the light emitting area;
a common electrode on the light emitting layer and the pixel defining film;
an encapsulation layer on the common electrode;
a first inorganic insulating film on the encapsulation layer;
a connection electrode on the first inorganic insulating film;
a second inorganic insulating film on the connection electrode and the first inorganic insulating film;
a touch electrode on the second inorganic insulating film and connected to the connection electrode through a touch contact hole penetrating through the second inorganic insulating film;
a third inorganic insulating film on the touch electrode;
a black matrix on the third inorganic insulating film;
a color filter on the third inorganic insulating film and covering a portion of the black matrix; and
a first optical hole penetrating through the first to third inorganic insulating films.

2. The display device of claim 1, wherein a refractive index of the color filter is lower than a refractive index of the first inorganic insulating film, a refractive index of the second inorganic insulating film, and a refractive index of the third inorganic insulating film.

3. The display device of claim 1, wherein in a plan view, a minimum distance from the pixel defining film to the first optical hole adjacent to the pixel defining film in one direction is shorter than a width of the first optical hole in the one direction.

4. The display device of claim 1, wherein in a plan view, a minimum distance from the pixel defining film to the black matrix adjacent to the pixel defining film in one direction is greater than a width of the first optical hole.

5. The display device of claim 1, wherein the color filter fills an entirety of the first optical hole.

6. The display device of claim 1, wherein the black matrix is spaced apart from the first optical hole.

7. The display device of claim 1, wherein the color filter fills a portion of the first optical hole.

8. The display device of claim 7, wherein the black matrix fills a remaining portion of the first optical hole.

9. The display device of claim 1, wherein a portion of the third inorganic insulating film is on the first optical hole.

10. The display device of claim 9, wherein a refractive index of the third inorganic insulating film is lower than a refractive index of the first inorganic insulating film and a refractive index of the second inorganic insulating film.

11. The display device of claim 1, wherein an angle formed between a lower surface of the first inorganic insulating film and a side surface of the first optical hole is in a range of 50° to 70°.

12. The display device of claim 1, further comprising:
an organic film between the encapsulation layer and the color filter; and
a second optical hole defined between the organic film and the first inorganic insulating film, between the organic film and the second inorganic insulating film, and between the organic film and the third inorganic insulating film.

13. The display device of claim 12, wherein in a plan view, the first optical hole surrounds the second optical hole.

14. The display device of claim 12, wherein a refractive index of the organic film is lower than a refractive index of the color filter.

15. The display device of claim 12, wherein the organic film overlaps the light emitting layer.

16. The display device of claim 12, wherein a lower surface of the organic film is longer than an upper surface of the organic film, and
a side surface of the organic film is formed to flatly connect the upper and lower surfaces of the organic film.

17. A display device comprising:
a substrate;
a pixel electrode on one surface of the substrate;
a pixel defining film exposing a portion of the pixel electrode and defining a light emitting area;
a light emitting layer on the pixel electrode in the light emitting area;
a common electrode on the light emitting layer and the pixel defining film;
an encapsulation layer on the common electrode;
a plurality of inorganic insulating films on the encapsulation layer and a touch electrode between the plurality of inorganic insulating films;
a black matrix on the plurality of inorganic insulating films;
color filters on the plurality of inorganic insulating films and covering portions of the black matrix; and
an optical hole penetrating through the plurality of inorganic insulating films, wherein the color filters include:
a first color filter configured to transmit light of a first color;
a second color filter configured to transmit light of a second color different from the first color; and
a third color filter configured to transmit light of a third color different from the first and second colors.

18. The display device of claim 17, wherein in a plan view, a minimum length from the pixel defining film to an optical hole of the first color filter adjacent to the pixel defining film in one direction is defined as a first length,
in the plan view, a minimum length from the pixel defining film to an optical hole of the second color filter adjacent to the pixel defining film in one direction is defined as a second length, and
the second length is longer than the first length.

19. The display device of claim 17, wherein in the plan view, a minimum length from the pixel defining film to an optical hole of the third color filter adjacent to the pixel defining film in one direction is defined as a third length, and
the third length is longer than the second length.

20. An electronic device including a display device, the display device comprising:
a substrate;
a pixel electrode on one surface of the substrate;
a pixel defining film exposing a portion of the pixel electrode and defining a light emitting area;
a light emitting layer on the pixel electrode in the light emitting area;
a common electrode on the light emitting layer and the pixel defining film;
an encapsulation layer on the common electrode;
a first inorganic insulating film on the encapsulation layer;
a connection electrode on the first inorganic insulating film;
a second inorganic insulating film on the connection electrode and the first inorganic insulating film;
a touch electrode on the second inorganic insulating film and connected to the connection electrode through a touch contact hole penetrating through the second inorganic insulating film;
a third inorganic insulating film on the touch electrode;
a black matrix on the third inorganic insulating film;
a color filter on the third inorganic insulating film and covering a portion of the black matrix; and
a first optical hole penetrating through the first to third inorganic insulating films.
